(19) United States
(12) Patent Application Publication
(10) Pub. No.: US 2018/0143534 A1
(43) Pub. Date: May 24, 2018

(54) LIQUID EJECTION HEAD, METHOD FOR PRODUCING LIQUID EJECTION HEAD, AND PRINTING METHOD

(71) Applicant: CANON KABUSHIKI KAISHA, Tokyo (JP)

(72) Inventor: Hyou Takahashi, Fukushima-shi (JP)

(21) Appl. No.: 15/815,552

(22) Filed: Nov. 16, 2017

(30) Foreign Application Priority Data
Nov. 22, 2016 (JP) 2016-226551

(51) Int. Cl. G03F 7/038; G03F 7/16; G03F 7/20; G03F 7/32; B41J 2/14; B41J 2/16

(52) U.S. Cl. CPC G03F 7/038; G03F 7/162; G03F 7/168; B41J 2/1631; G03F 7/325; B41J 2/1433; B41J 2/162; G03F 7/2004

(57) ABSTRACT

A method for producing a liquid ejection head including an ejection surface having a cured product of a negative photosensitive resin composition includes the steps of applying the negative photosensitive resin composition to form a coating film, subjecting the coating film to exposure, and after the step of subjecting the coating film to exposure, performing heating at 120° C. or higher, in which the negative photosensitive resin composition contains a polymer (A) containing a unit originating from an epoxy group-containing acrylic ester and at least one selected from a unit originating from acrylic acid and a unit originating from an acrylic ester capable of being deprotected at 120° C. or higher.

### BACKGROUND

### Field of the Disclosure

The present disclosure relates to a method for producing a liquid ejection head, a liquid ejection head, and a printing method.

### Description of the Related Art

In recent years, with regard to inkjet printheads, inks containing pigments have been increasingly used from the viewpoint of achieving high durability of printed images. In the case of using inks containing pigments, however, ink components are liable to be solidified, depending on compositions. For example, when a solidified ink component is left near an ejection orifice that ejects an ink, there are problems such as the deflection of the fly direction of an ink droplet and a decrease in the ejection speed of an ink droplet.

As a method for inhibiting the occurrence of the problems and ejecting an ink with high accuracy, Japanese Patent Laid-Open No. 2011-206628 discloses a method for inhibiting the solidification of an ink component by spraying ions on an ejection surface of an ink to eliminate static. Japanese Patent Laid-Open No. 2011-206628 states that the occurrence of the solidification of the ink component is attributed to the charge of static electricity of the ejection surface.

### SUMMARY OF THE DISCLOSURE

The present disclosure is directed to providing a highly hydrophilic liquid ejection head with an ejection surface having improved resistance to the charge of static electricity owing to the properties of the material of the ejection surface, the liquid ejection head being capable of inhibiting the solidification of an ink component at the ejection surface even in the case of using a pigment-containing ink, the liquid ejection head having high ink resistance owing to the material of the ejection surface and being capable of maintaining hydrophilicity even if the ejection surface is exposed to the pigment-containing ink.

One aspect of the present disclosure is directed to providing a method for producing a liquid ejection head including an ejection surface having the cured product of a negative photosensitive resin composition, the method including the steps of applying the negative photosensitive resin composition to form a coating film, subjecting the coating film to exposure, and after the step of subjecting the coating film to exposure, performing heating at 120° C. or higher, in which the negative photosensitive resin composition contains a polymer (A) containing a unit originating from an epoxy group-containing acrylic ester and at least one selected from a unit originating from acrylic acid and a unit originating from an acrylic ester capable of being deprotected at 120° C. or higher.

Another aspect of the present disclosure is directed to providing a liquid ejection head including an ejection surface having a cured product of a negative photosensitive resin composition, in which the negative photosensitive resin composition contains a polymer (A) containing a unit originating from an epoxy group-containing acrylic ester and at least one selected from a unit originating from acrylic acid and a unit originating from an acrylic ester capable of being deprotected at 120° C. or higher, the cured product containing a carboxy group.

Further features of the present disclosure will become apparent from the following description of exemplary embodiments with reference to the attached drawings.

### BRIEF DESCRIPTION OF THE DRAWINGS

FIG. 1 is a schematic perspective view of a liquid ejection head according to an embodiment of the present disclosure.

FIGS. 2A to 2G are cross-sectional views illustrating the steps of a method for producing a liquid ejection head according to an embodiment of the present disclosure.

### DESCRIPTION OF THE EMBODIMENTS

Studies by the inventors have indicated that in the method disclosed in Japanese Patent Laid-Open No. 2011-206628, a device for eliminating static electricity and a gas blower are required to be arranged near an ejection surface, which makes it difficult to reduce the size of a liquid ejection apparatus. Even if the formation of sticking matter can be inhibited, the exposure of the ejection surface to an ink for a long time changes the properties, such as liquid repellency, of the ejection surface, in some cases.

An embodiment of the present disclosure provides a highly hydrophilic liquid ejection head that inhibits the solidification of an ink component at an ejection surface even in the case of using a pigment-containing ink, the liquid ejection head having high ink resistance and being capable of maintaining hydrophilicity even if the ejection surface is exposed to the pigment-containing ink.

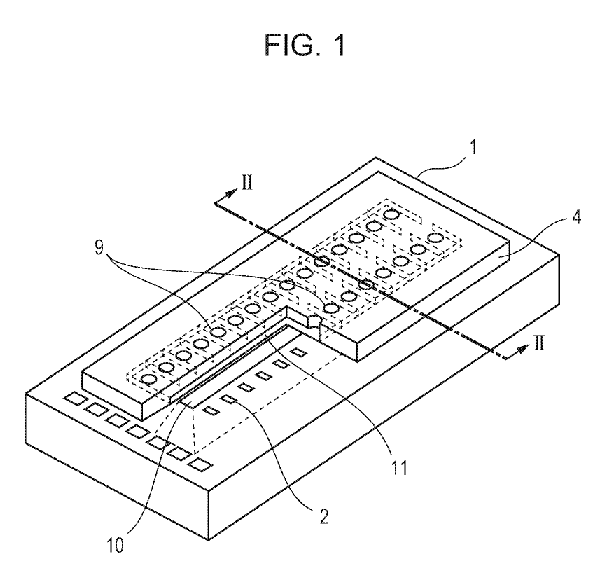

Embodiments of the present disclosure will be described in detail below. The structure of a liquid ejection head according to an embodiment of the present disclosure is described with reference to FIG. 1.

### Liquid Ejection Head

As illustrated in FIG. 1, a liquid ejection head according to an embodiment of the present disclosure includes a substrate 1 that includes energy-generating elements 2 to impart ejection energy to a liquid and a member 4 having ejection orifices 9 to eject the liquid on the substrate 1. A hydrophilic layer 5 (not illustrated) composed of the cured product of a negative photosensitive resin composition is arranged on a portion of the member 4 where the ejection orifices 9 are arranged (ejection surface). A liquid channel 11 communicating with the ejection orifices 9 is arranged between the substrate 1 and the member 4. The substrate 1 also includes a supply port 10 to supply the liquid. In the liquid ejection head having this structure, the energy-generating elements 2 imparts energy to the liquid supplied from the supply port 10 to the liquid channel 11 to eject the liquid from the ejection orifices 9.

As described above, the liquid ejection head according to an embodiment of the present disclosure is a liquid ejection head including an ejection surface having the cured product of a negative photosensitive resin composition. The negative photosensitive resin composition contains a polymer (A) containing a unit originating from an epoxy group-containing acrylic ester and at least one selected from a unit originating from acrylic acid and a unit originating from an acrylic ester capable of being deprotected at 120° C. or higher, the cured product containing a carboxy group.

Hereinafter, in the polymer (A), the unit originating from an epoxy group-containing acrylic ester is also referred to as “(a1)”, the unit originating from acrylic acid is also referred to as “(a2)”, and the unit originating from an acrylic ester capable of being deprotected at 120° C. or higher is also referred to as “(a3).

An liquid ejection head according to an embodiment of the present disclosure is produced by a production method including a step (c) of applying the negative photosensitive resin composition to form a coating film, a step (d) of subjecting the coating film to exposure, and after the step of subjecting the coating film to exposure, a step of performing heating at 120° C. or higher. The step of performing heating at 120° C. or higher may be performed anytime as long as it is performed after the step (d) of performing exposure. Details of the steps are described below.

As an example, the case where heating is performed at 140° C. for 4 minutes is described as the step of performing heating at 120° C. or higher after a step (f) of removing an unexposed portion by development to form the ejection orifices 9. In this case, chemical changes that are presumed to occur in the polymer (A) contained in the negative photosensitive resin composition in the steps are illustrated below. In the formulae illustrated below, the case where the polymer (A) is a copolymer in which the feeding molar ratio of (a1) to (a3) is 40:60 is illustrated.

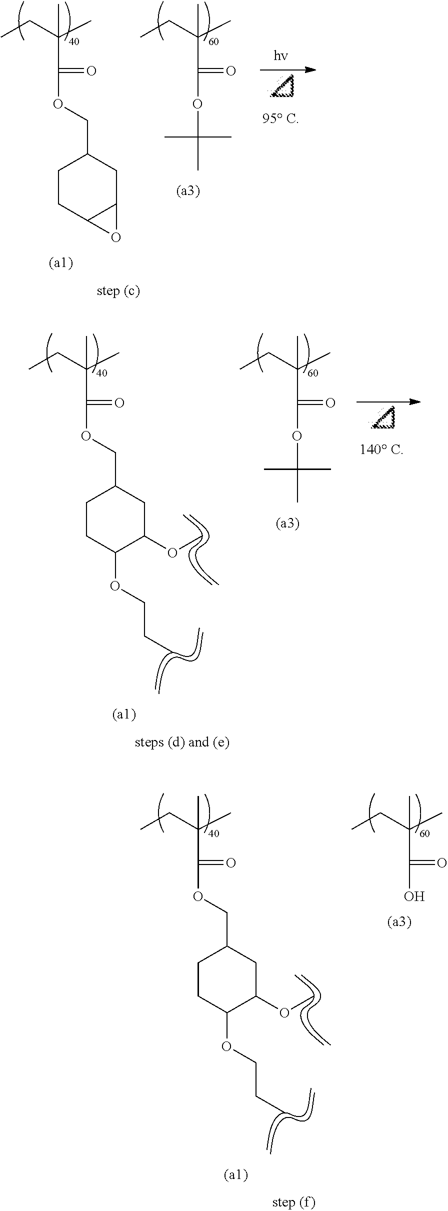

In the step (c) of applying a negative photosensitive resin composition to form a coating film, an organic solvent in the composition is evaporated to dry the polymer (A). In this step, however, no acid serving as a catalyst is present; thus, the polymerization reaction of an epoxide in (a1) and the deprotection reaction of an ester in (a3) are less likely to proceed or proceed little. The polymer (A), therefore, maintains the same chemical structure as before the application of the negative photosensitive resin composition.

In the step (d) of subjecting the coating film to exposure and the step (e) of curing an exposed portion, exposure and post-exposure bake (PEB) at 95° C. are performed. In these steps, the catalytic action of an acid formed from a photopolymerization initiator that has been exposed to light allows the polymerization reaction of the epoxide in (a1) to proceed partially to form covalent bonds in the hydrophilic layer 5 and between the member 4 and the hydrophilic layer 5. This improves the adhesion between the member 4 and the hydrophilic layer 5 to provide robustness against a development step. The deprotection reaction of the ester in (a3), however, does not easily proceed in the coating film at lower than 120° C. Even if the deprotection reaction proceeds, the deprotection reaction seems to proceed only partially. Thus, when heating is performed at 140° C. after the unexposed portion is removed by development to form the ejection orifices 9 in the next step (f), the deprotection reaction of the ester in (a3) seemingly proceeds to form a carboxy group.

In the case where the liquid ejection head produced by the production method described above is used, the occurrence of the sticking of a pigment-containing ink can be inhibited on the ejection surface. The mechanism thereof seems to be as follows: the absorption of water in air by carboxy groups originating from the negative photosensitive resin composition arranged on the ejection surface allows the presence of conductive water on the ejection surface; and a component that causes the ink to stick is repelled by negative charges to inhibit the solidification or aggregation of the ink component on the ejection surface.

Fine pigment particles serving as a fixing component of the ink and a resin added to disperse the fine pigment particles have a structure in which negative charges are arranged toward water and a polar solvent present outside. Thus, the fact that the negative charges are repelled from negative charges present on the ejection surface is seemingly effective as a method for inhibiting the solidification or aggregation of the ink component on the ejection surface. To inhibit the formation of sticking matter on the ejection surface, it is important to form a large amount of negatively chargeable groups, i.e., hydrophilic groups such as carboxy and hydroxy groups, on the ejection surface. To maintain high hydrophilicity over a long period of time even if the ejection surface is exposed to the ink, it seems to be necessary to form a strong covalent three-dimensional network in the hydrophilic layer 5 and between the member 4 and the hydrophilic layer 5.

The liquid ejection head capable of inhibiting the formation of sticking matter to maintain high hydrophilicity on the ejection surface even in the case of using the pigment-containing ink is produced by the production method according to an embodiment of the present disclosure. The liquid ejection head according to an embodiment of the present disclosure can be suitably used as an inkjet recording head.

The negative photosensitive resin composition contained in the hydrophilic layer 5 of the liquid ejection head according to an embodiment of the present disclosure will be described below.

### Negative Photosensitive Resin Composition

The negative photosensitive resin composition according to an embodiment of the present disclosure contains the polymer (A) containing the unit (a1) originating from an epoxy group-containing acrylic ester and at least one selected from the unit (a2) originating from acrylic acid and the unit (a3) originating from an acrylic ester capable of being deprotected at 120° C. or higher. The negative photosensitive resin composition may contain, for example, a photopolymerization initiator (B), an organic solvent, and other additives. Components contained in the negative photosensitive resin composition will be described below.

### Polymer (A)

The polymer (A) contains the unit (a1) originating from an epoxy group-containing acrylic ester and at least one selected from the unit (a2) originating from acrylic acid and the unit (a3) originating from an acrylic ester capable of being deprotected at 120° C. or higher. The polymer (A) may further contain at least one of a unit that originates from an acrylic ester and that is not capable of being deprotected at 120° C. or higher and a unit originating from optionally substituted styrene. Hereinafter, the unit that originates from an acrylic ester and that is not capable of being deprotected at 120° C. or higher or the unit originating from optionally substituted styrene is also referred to as “(a4)”.

(a1) Unit Originating from Epoxy Group-Containing Acrylic Ester

In the case where the polymer (A) contains (a1), the epoxy groups in the unit form covalent bonds in the hydrophilic layer 5 and between the member 4 and the hydrophilic layer 5 by an epoxy polymerization reaction to form a strong three-dimensional network, thereby providing the liquid ejection head having high ink resistance and being capable of maintaining hydrophilicity even if the ejection surface is exposed to an ink for a long period of time. (a1) is a unit originating from an acrylic ester and is not particularly limited as long as it has a structure containing an epoxy group. Specifically, (a1) can have a structure selected from structures represented by formulae (a1-1) to (a1-4):

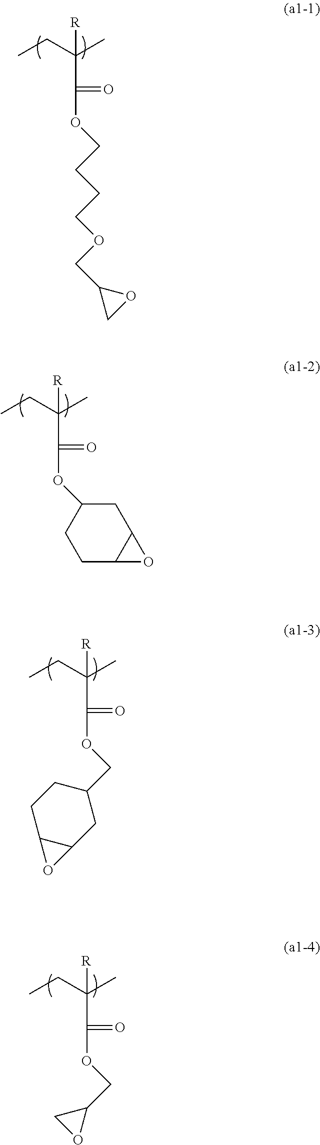

In each of formulae (a1-1) to (a1-4), R represents a hydrogen atom, a fluorine atom, an alkyl group having 1 to 4 carbon atoms such as a methyl group, a phenyl group, a hydroxy group, a carboxy group, or a cyano group. R can represent a hydrogen atom or a methyl group. Among these, (a1) can have a structure selected from the structures represented by formulae (a1-2) to (a1-4).

The proportion (copolymerization ratio) of (a1) in the polymer (A) is preferably 20% or more and 80% or less, more preferably 25% or more and 70% or less in terms of a feeding molar ratio. When the proportion of (a1) is 20% or more, covalent bonds are sufficiently formed to easily improve the ink resistance. When the proportion of (a1) is 80% or less, hydrophilic groups are sufficiently contained; thus, the sticking and aggregation of the ink component on the ejection surface can be more efficiently inhibited.

(a2) Unit Originating from Acrylic Acid

In the case where the polymer (A) contains (a2), carboxy groups that originate from (a2) and that are ultimately arranged on the ejection surface absorb water in air, thus resulting in the presence of conductive water on the ejection surface. The component that causes the sticking of an ink is repelled by the negative charges, thus enabling inhibition of the sticking and aggregation of the ink component on the ejection surface. Furthermore, (a2) is effective as a component that promotes the dissolution of the polymer (A) in a polar solvent such as an alcohol. Specifically, (a2) can have a structure selected from structures represented by formulae (a2-1) to (a2-6). Of these, (a2) can have a structure represented by formula (a2-1) or (a2-2):

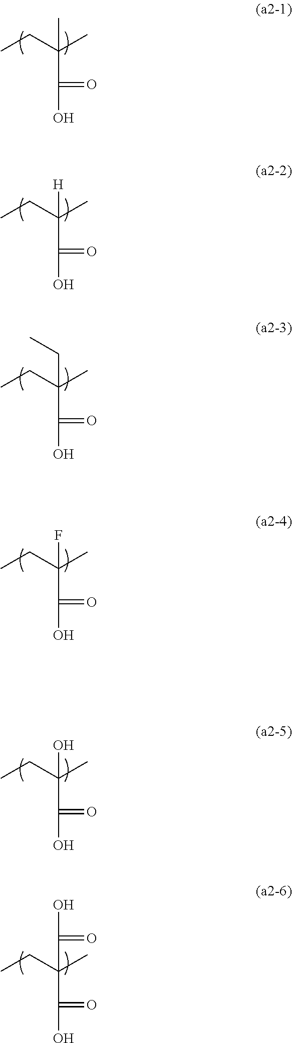

The proportion of (a2) in the polymer (A) is preferably 80% or less, more preferably 50% or less in terms of a feeding molar ratio. When the proportion of (a2) is 80% or less, an improved solubility of the polymer (A) in a solvent is provided to inhibit the precipitation. The effect of inhibiting the sticking or aggregation of the ink component is also provided by carboxy groups originating from (a3) described below. Thus, when (a3) is used, the proportion of (a2) may be 0%.

(a3) Unit Originating from Acrylic Ester Capable of Being Deprotected at 120° C. or Higher

In the case where the polymer (A) contains (a3), carboxy groups that originate from (a3) and that are ultimately arranged on the ejection surface absorb water in air, thus resulting in the presence of conductive water on the ejection surface. The component that causes the sticking of an ink is repelled by the negative charges, thus enabling inhibition of the sticking and aggregation of the ink component on the ejection surface. The acrylic ester capable of being deprotected at 120° C. or higher refers to an acrylic ester in which although the deprotection reaction of the ester is less likely to proceed or proceeds little at lower than 120° C., the deprotection reaction of the ester proceeds at 120° C. or higher. That is, the difference between (a3) and (a2) is that heating at 120° C. or higher allows the deprotection reaction of the ester to occur to form a carboxy group.

The carboxy group can react with the epoxy group in (a1), depending on reaction conditions. In the case where the polymer (A) contains (a1) and (a2), carboxy groups and epoxy groups are present, and some of the carboxy groups are consumed by a reaction with the epoxy groups. In the case where the polymer (A) contains (a1) and (a3), after the epoxy groups in (a1) are consumed by an epoxy polymerization reaction, the esters in (a3) are subjected to a deprotection reaction by heating at 120° C. or higher to form carboxy groups originating from (a3). Thus, the amount of carboxy groups consumed by the reaction with the epoxy groups is small, so that a large amount of carboxy groups can be ultimately formed on the ejection surface. Therefore, the polymer (A) can contain (a1) and (a3).

(a3) is not particularly limited as long as it is a unit originating from an ester capable of being deprotected at 120° C. or higher. Specifically, (a3) can have a structure selected from structures represented by formulae (a3-1) to (a3-30):

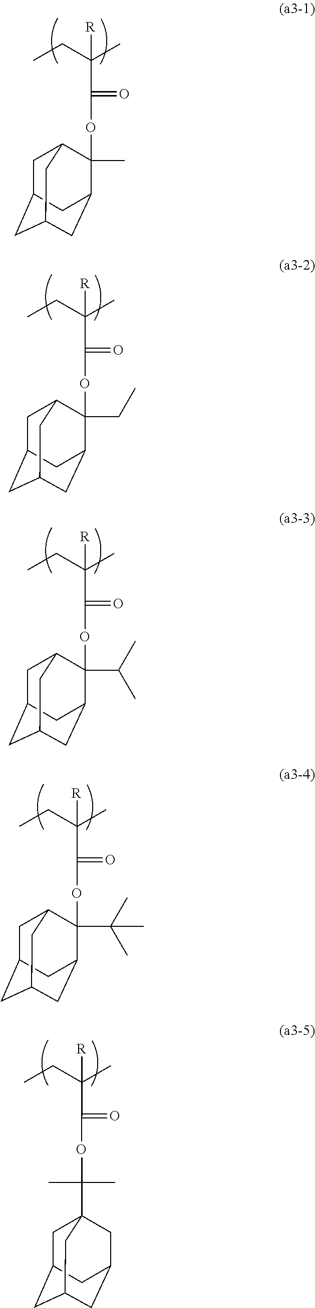

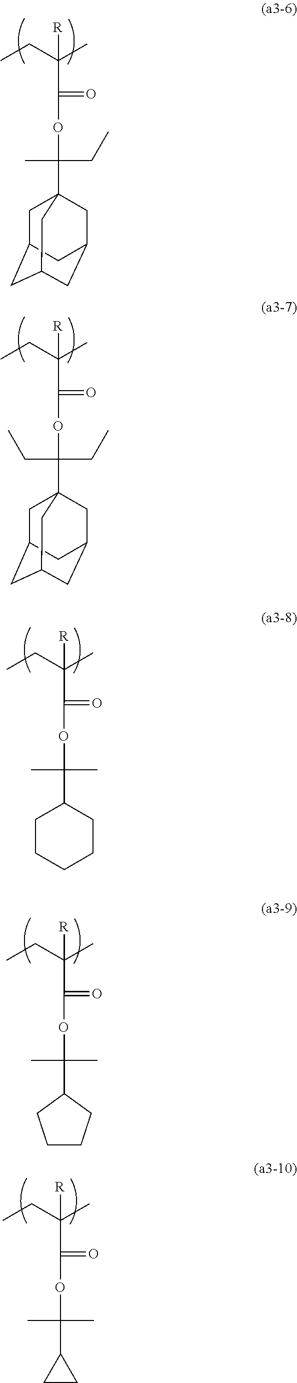

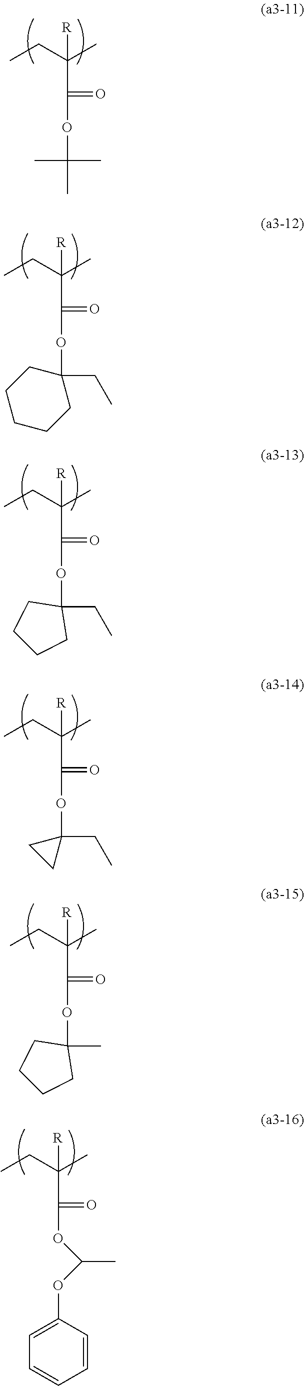

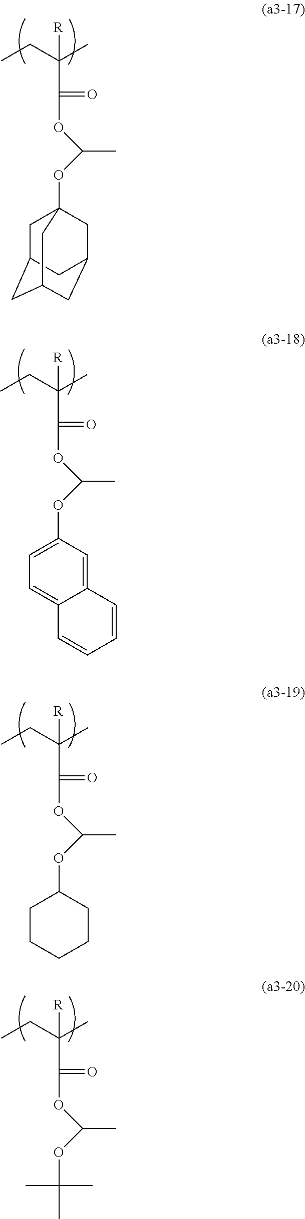

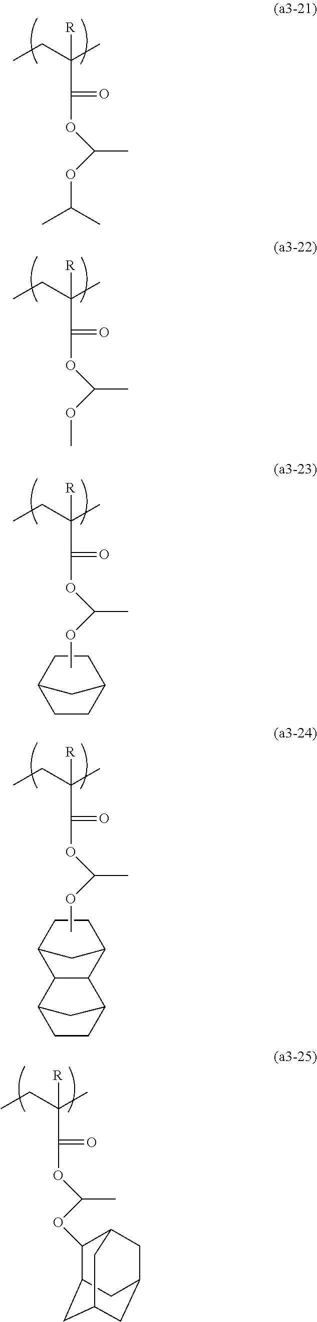

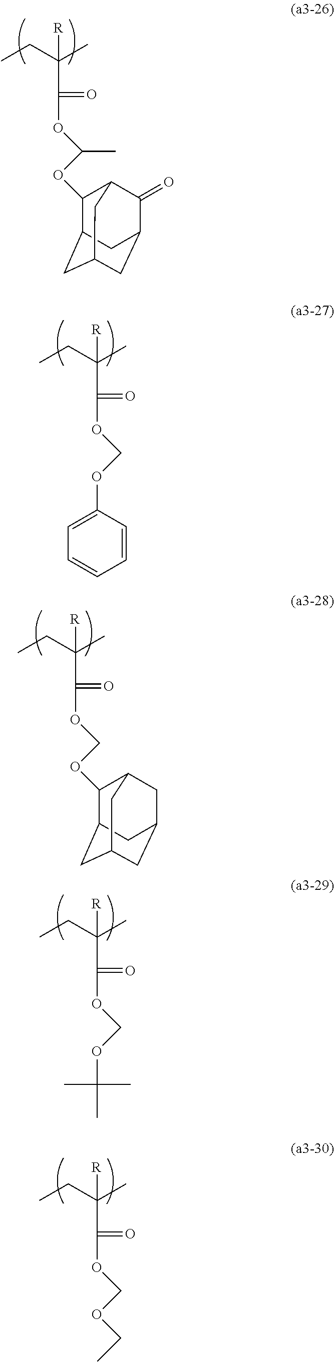

In each of formulae (a3-1) to (a3-30), R represents a hydrogen atom, a fluorine atom, an alkyl group having 1 to 4 carbon atoms such as a methyl group, a phenyl group, a hydroxy group, a carboxy group, or a cyano group. R can represent a hydrogen atom or a methyl group. Among these, (a3-1) to (a3-15) and (a3-16), which are units originating from tertiary alkyl esters, are more preferred. (a3-1), (a3-2), (a3-5), (a3-8), (a3-11), (a3-13), and (a3-16) are even more preferred. (a3-1), (a3-2), (a3-5), (a3-11), and (a3-13) are particularly preferred.

The proportion of (a3) in the polymer (A) is preferably 20% or more and 80% or less, more preferably 25% or more and 75% or less in terms of a feeding molar ratio. When the proportion of (a3) is 20% or more, hydrophilic groups are sufficiently contained; thus, the sticking and aggregation of the ink component on the ejection surface can be inhibited. When the proportion of (a3) is 80% or less, covalent bonds are sufficiently formed to easily improve the ink resistance.

(a4) Unit that Originates from Acrylic Ester and that is not Capable of being Deprotected at 120° C. or Higher or Unit Originating from Optionally Substituted Styrene

When the polymer (A) contains (a4), the properties of the polymer (A), such as the solubility of the polymer (A) in a solvent, the affinity with an underlying layer at the time of the formation of the coating film, and the coating properties, are easily adjusted. The acrylic ester that is not capable of being deprotected at 120° C. or higher refers to an acrylic ester in which the ester is not deprotected even at 120° C. or higher and the ester structure is maintained.

(a4) is not particularly limited as long as it is a unit that originates from an acrylic ester and that is not capable of being deprotected at 120° C. or higher or it is a unit originating from an optionally substituted styrene. Examples of a substituent that may be attached to the styrene include a fluorine atom, alkyl groups having 1 to 4 carbon atoms such as a methyl group, a phenyl group, a hydroxy group, a carboxy group, and a cyano group. Specifically, (a4) can have a structure selected from structures represented by formulae (a4-1) to (a4-24):

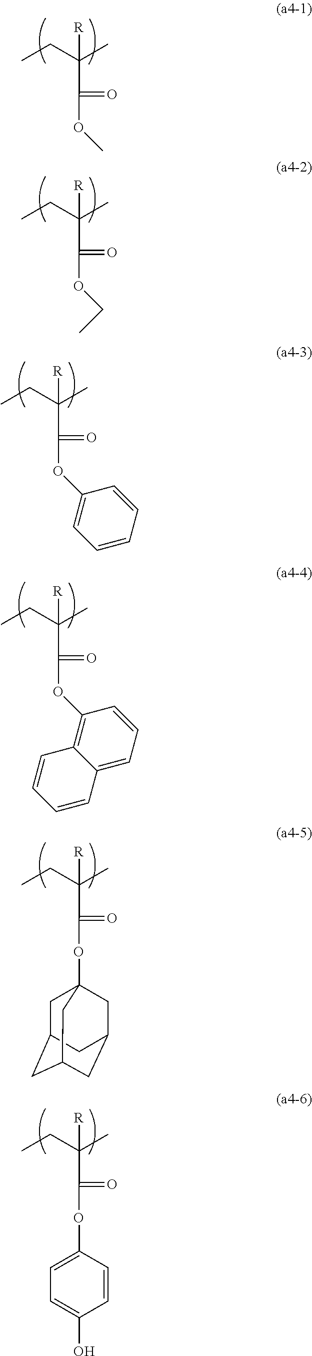

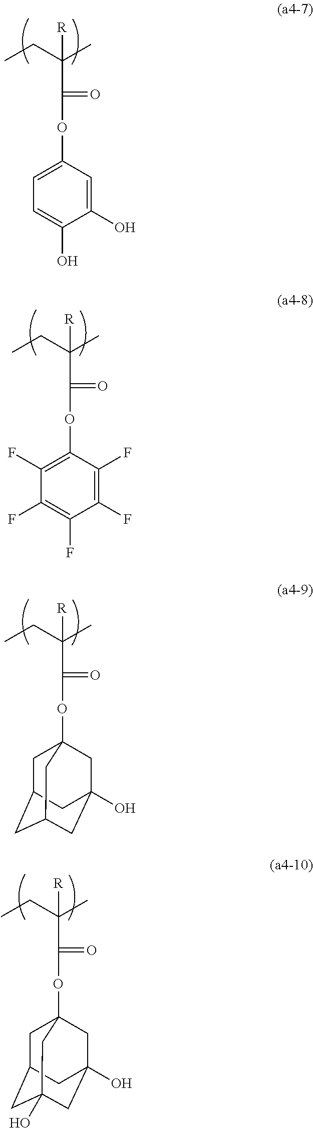

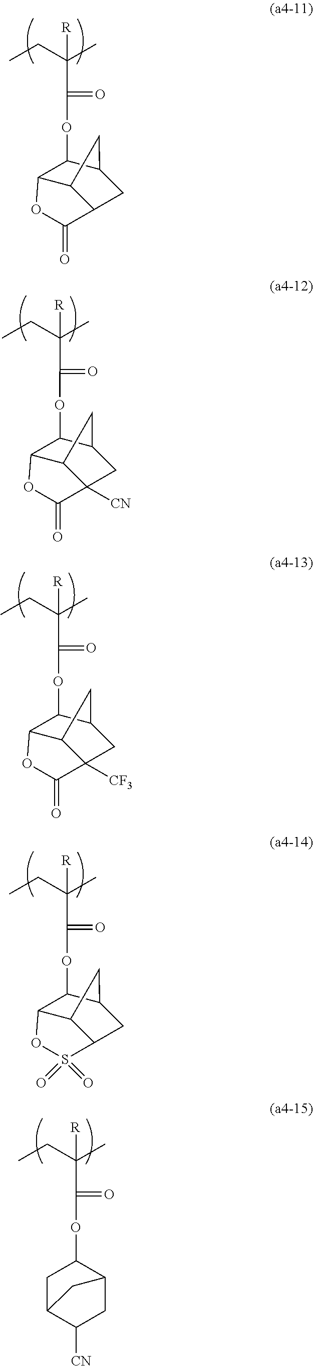

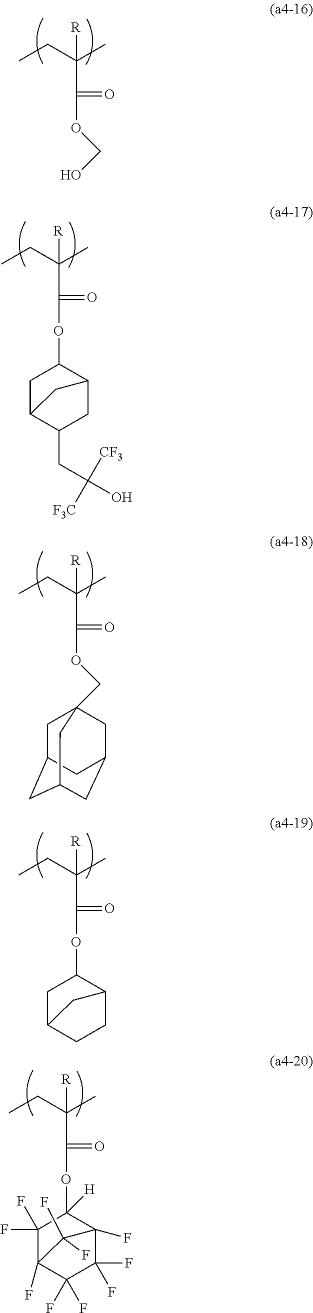

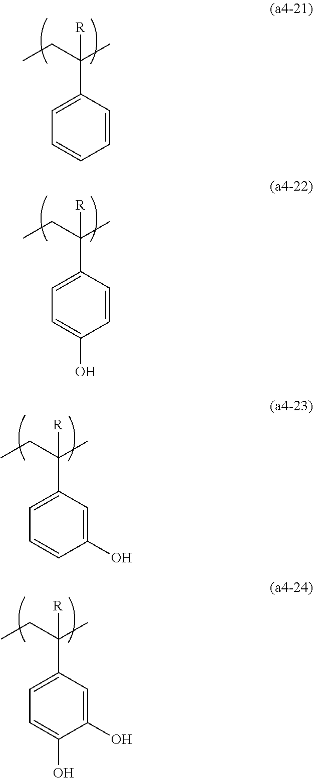

In each of formulae (a4-1) to (a4-24), R represents a hydrogen atom, a fluorine atom, an alkyl group having 1 to 4 carbon atoms such as a methyl group, a phenyl group, a hydroxy group, a carboxy group, or a cyano group. R can represent a hydrogen atom or a methyl group. Among these, (a4) can have a structure selected from the structures represented by formulae (a4-1), (a4-11), (a4-21), and (a4-22).

The proportion of (a4) in the polymer (A) is preferably 50% or less, more preferably 40% or less in terms of a feeding molar ratio. When the proportion of (a4) is 50% or less, covalent bonds are sufficiently formed to easily improve the ink resistance. Furthermore, hydrophilic groups are sufficiently contained; thus, the sticking and aggregation of the ink component on the ejection surface can be more efficiently inhibited.

### Polymer (A)

The polymer (A) can have a mass-average molecular weight (Mw), determined by gel permeation chromatography, of 800 to 500,000 in terms of polystyrene. When the polymer (A) has a mass-average molecular weight of 800 or more, an improved ink resistance is easily provided, thus easily maintaining high hydrophilicity over a long period of time. When the polymer (A) has a mass-average molecular weight of 500,000 or less, an improved solubility in a solvent is provided, so that the precipitation thereof can be inhibited.

The polymer (A) preferably has a polydispersity (Mw/Mn) of 1.0 to 5.0, more preferably 1.0 to 4.0. Mn represents a number-average molecular weight.

The polymer (A) is not particularly limited as long as it appropriately contains a unit selected from (a1) to (a4) within a range specified by an embodiment of the present disclosure. The polymer (A) can have a structure selected from structures represented by formulae (A-1) to (A-7):

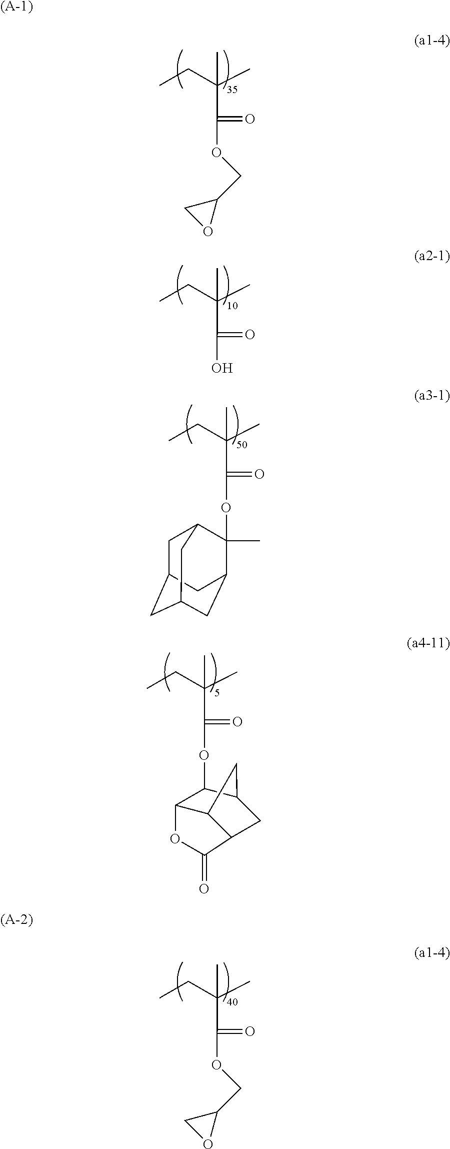

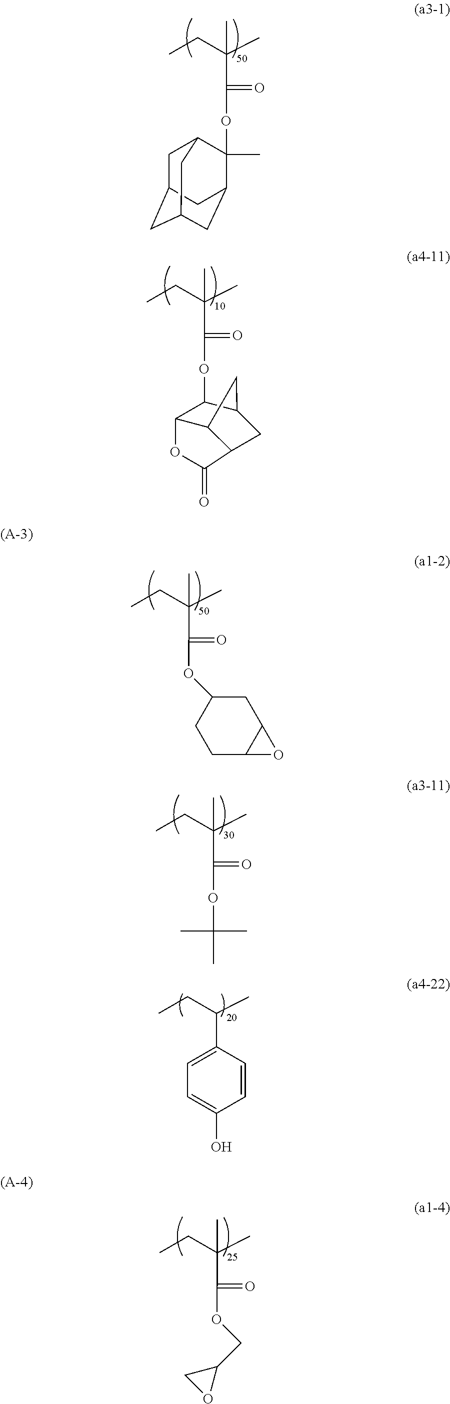

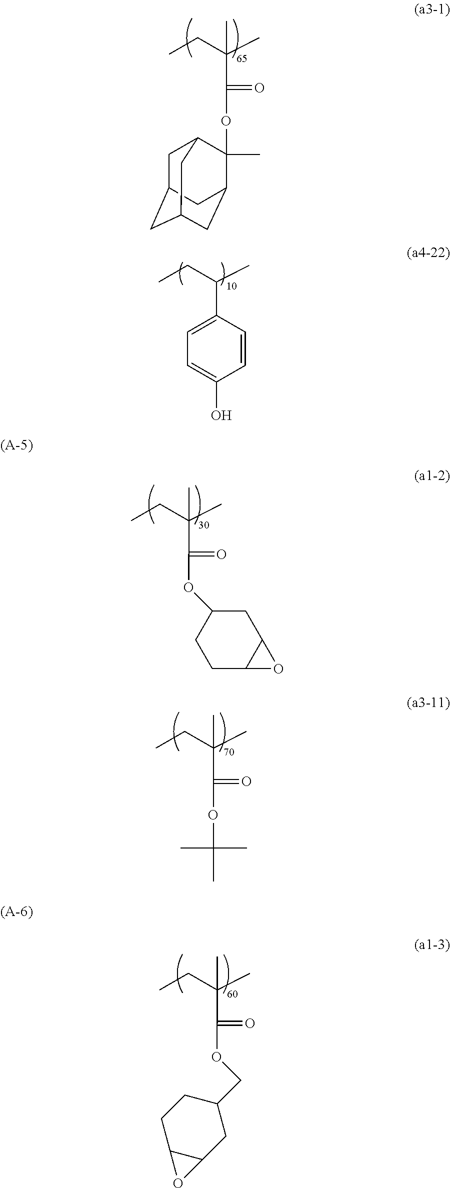

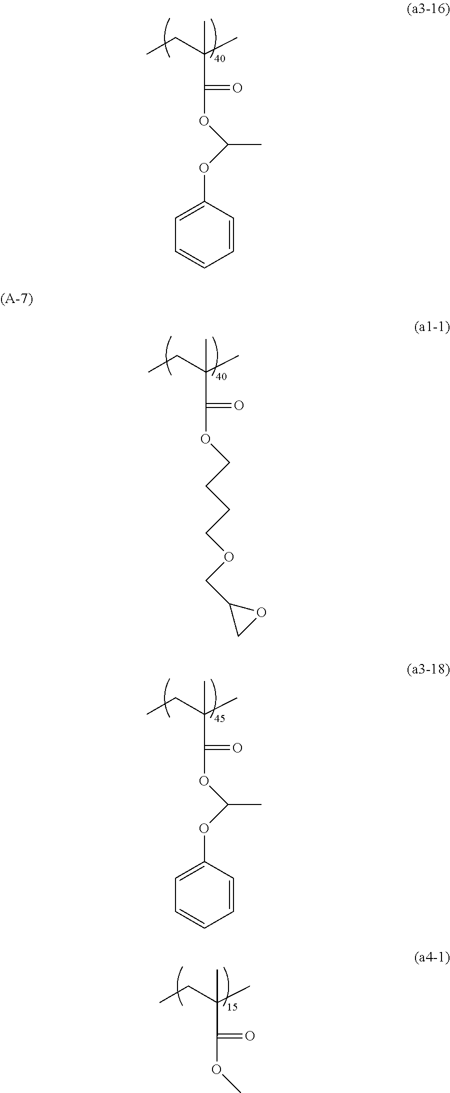

A single type of the polymer (A) can be used. Alternatively, two or more types of the polymer (A) can be used in combination. The negative photosensitive resin composition preferably has a polymer (A) content of 45% or more by mass and 99.9% or less by mass, more preferably 55% or more by mass and 99.9% or less by mass, even more preferably 60% or more by mass and 99.2% or less by mass based on the total solid content of the negative photosensitive resin composition. When the negative photosensitive resin composition has a polymer (A) content within the range described above, a more improved effect of inhibiting the sticking or aggregation of the ink component on the ejection surface is provided.

### Photopolymerization Initiator (B)

The negative photosensitive resin composition according to an embodiment of the present disclosure may contain a photopolymerization initiator (B) in order to promote the epoxy polymerization reaction and the ester deprotection reaction in the polymer (A). However, in the case where the photopolymerization initiator contained in a cover layer 4a is diffused in a coating film 5a at the time of the application of the negative photosensitive resin composition, the same effect is provided by the photopolymerization initiator; thus, the negative photosensitive resin composition need not contain a photopolymerization initiator.

The photopolymerization initiator (B) may have any structure as long as it is sensitive to ultraviolet light. For example, an ionic onium salt such as a sulfonium salt or an iodonium salt can be used. However, an onium salt containing an anion of P(CF₃)₃F₃, which is a fluorine-substituted phosphorous compound, SbF₆, which is an antimony compound, or B(C₆F₅)₄, which is a fluorine-substituted boron compound, can be used in view of the degree of cationic polymerization activity. Examples of a commercially available photopolymerization initiator include Adeka Optomer SP-172 (trade name, available from Adeka Corporation) and CPI (registered trademark)-410S (trade name, available from San-Apro Ltd).

The photopolymerization initiator (B) is preferably sensitive to the i-line or KrF light, which has a single wavelength, more preferably the i-line. In the case of a liquid ejection head such as inkjet recording head, sticking matter on an ejection surface often has a thickness on the order of micrometers. In the case of using a single-wavelength light source, thus, a light source corresponding to the thickness can be selected in view of the depth of focus.

Examples of the photopolymerization initiator (B) sensitive to the i-line, which is light having a wavelength of 365 nm, include onium salts having a cation structure represented by formula (b1) and an anion structure represented by formula (b2):

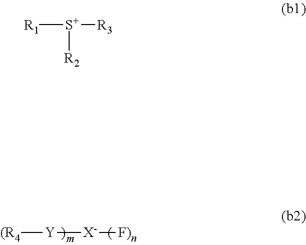

R₁ to R₃ in formula (b1) each independently represent an organic group having 1 to 30 carbon atoms, provided that the cation structure represented by formula (b1) contains two or more oxygen atoms. The cation structure represented by formula (b1) can have at least one backbone selected from the group consisting of a thioxanthone backbone, a 9,10-dialkoxyanthracene backbone, and an anthraquinone backbone. The two or more oxygen atoms in the cation structure include oxygen atoms contained in the thioxanthone backbone, the 9,10-dialkoxyanthracene backbone, and the anthraquinone backbone. The cation structure may have a plurality of thioxanthone backbones, a plurality of 9,10-dialkoxyanthracene backbones, or a plurality of anthraquinone backbones. Because the photopolymerization initiator (B) has the cation structure represented by formula (b1), the absorption wavelength shifts to longer wavelengths, so that the resulting negative photosensitive resin composition is sensitive to the i-line.

Examples of the organic group represented by R₁ to R₃ include alkyl groups having 1 to 30 carbon atoms, alkenyl groups having 2 to 30 carbon atoms, alkynyl groups having 2 to 30 carbon atoms, aryl groups having 6 to 30 carbon atoms, and heterocyclic groups having 4 to 30 carbon atoms; groups in which at least some hydrogen atoms contained in these groups are replaced with halogen atoms such as fluorine atoms, alkyl groups having 1 to 8 carbon atoms such as a methyl group, hydroxy groups, amino groups, cyano groups, or nitro groups; and groups in which an ether linkage, a thioether linkage, a carbonyl group, an oxycarbonyl group, a thiocarbonyl group, a sulfinyl group, or a sulfonyl group is interposed between the C—C bonds of these groups, provided that the number of carbon atoms is 30 or less. Two or more of R₁ to R₃ may be bonded together to form a ring structure.

X in formula (b2) represents an atom selected from the group consisting of a carbon atom, a nitrogen atom, a phosphorus atom, a boron atom, and an antimony atom. Y represents a linking group selected from the group consisting of —S(═O)₂—, —CF₂—O—, —CF₂—C(═O)—, —CF₂—C(═O)—O—, —CF₂—O—C(═O)—, and a single bond.

R₄ represents a hydrocarbon group that has 1 to 30 carbon atoms and that may be substituted with a fluorine atom. When Y represents —S(═O)₂— or a single bond, R₄ contains at least one fluorine atom. Examples of the hydrocarbon group that has 1 to 30 carbon atoms and that may be substituted with a fluorine atom include alkyl groups having 1 to 30 carbon atoms, aryl groups having 6 to 30 carbon atoms, groups in which at least some hydrogen atoms of these groups are replaced with fluorine atoms.

When X represents a carbon atoms, m and n represent integers that satisfy m+n=3, and n=0 to 2. When X represents a nitrogen atom, m and n integers that satisfy m+n=2, and n=0 to 1. When X represents a phosphorus atom or an antimony atom, m and n represent integers that satisfy m+n=6, and n=0 to 6. When X represents a boron atom, m and n represent integers that satisfy m+n=4, and n=0 to 3. When m represents an integer of 2 or more as illustrated in formula (b2-10), two or more of R₄ may be bonded together to form a ring structure.

Specific examples of the cation structure represented by formula (b1) and the anion structure represented by formula (b2) are illustrated below:

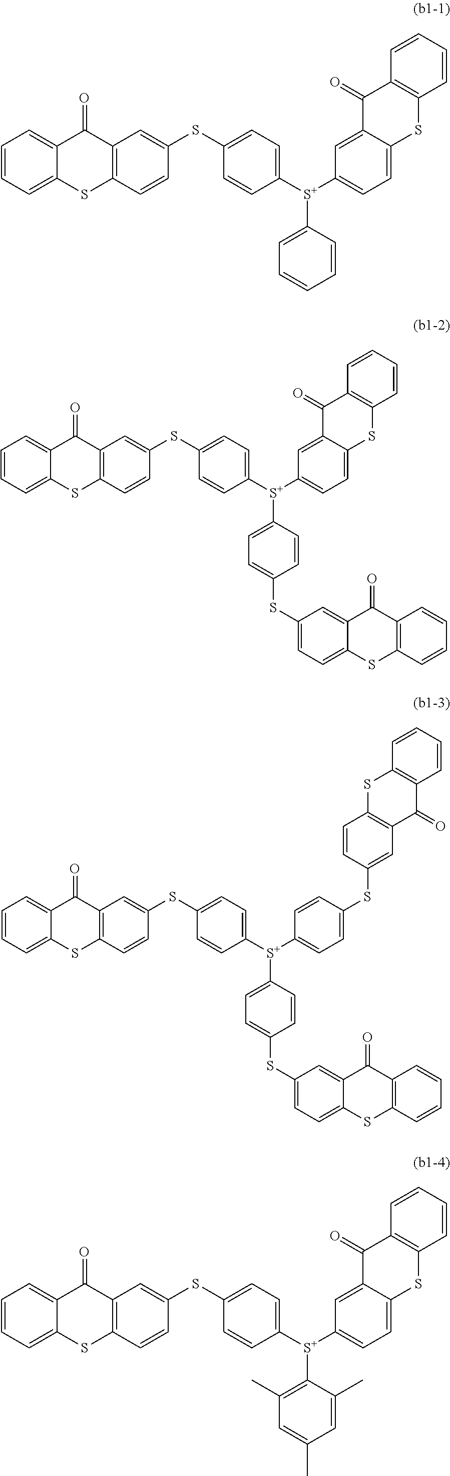 [SMILES: O=c1c2ccccc2sc2ccc(Sc3ccc([S+](c4ccccc4)c4ccc5sc6ccccc6c(=O)c5c4)cc3)cc12 ; O=c1c2ccccc2sc2ccc(Sc3ccc([S+](c4ccc(Sc5ccc6sc7ccccc7c(=O)c6c5)cc4)c4ccc5sc6ccccc6c(=O)c5c4)cc3)cc12 ; O=c1c2ccccc2sc2ccc(Sc3ccc([S+](c4ccc(Sc5ccc6sc7ccccc7c(=O)c6c5)cc4)c4ccc(Sc5ccc6sc7ccccc7c(=O)c6c5)cc4)cc3)cc12 ; Cc1cc(C)c([S+](c2ccc(Sc3ccc4sc5ccccc5c(=O)c4c3)cc2)c2ccc3sc4ccccc4c(=O)c3c2)c(C)c1]

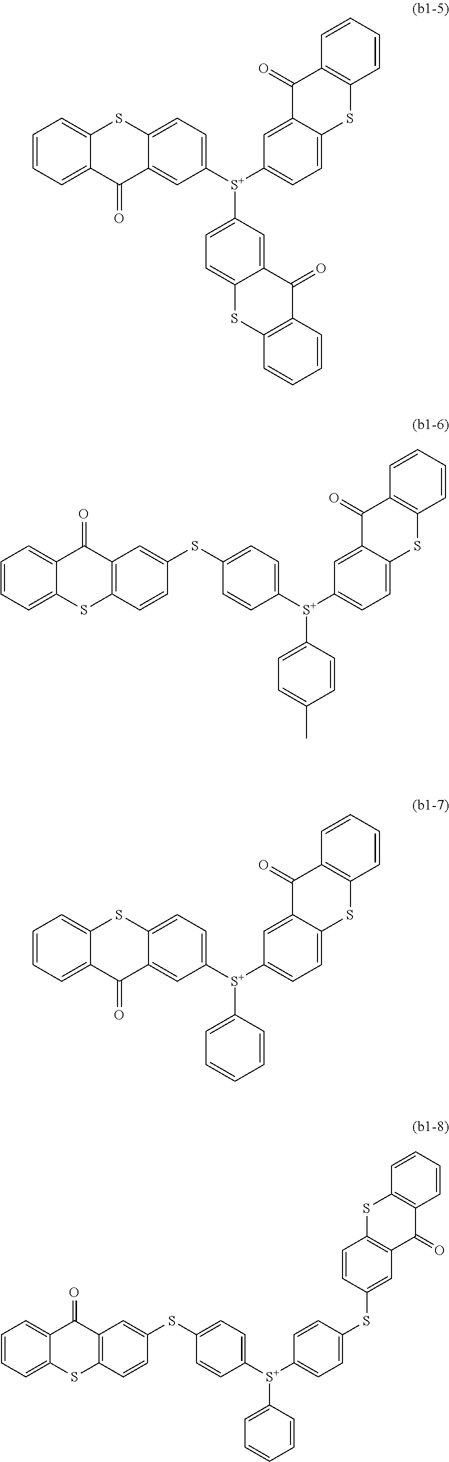 [SMILES: O=c1c2ccccc2sc2ccc([S+](c3ccc4sc5ccccc5c(=O)c4c3)c3ccc4sc5ccccc5c(=O)c4c3)cc12 ; Cc1ccc([S+](c2ccc(Sc3ccc4sc5ccccc5c(=O)c4c3)cc2)c2ccc3sc4ccccc4c(=O)c3c2)cc1 ; O=c1c2ccccc2sc2ccc([S+](c3ccccc3)c3ccc4sc5ccccc5c(=O)c4c3)cc12 ; O=c1c2ccccc2sc2ccc(Sc3ccc([S+](c4ccccc4)c4ccc(Sc5ccc6sc7ccccc7c(=O)c6c5)cc4)cc3)cc12]

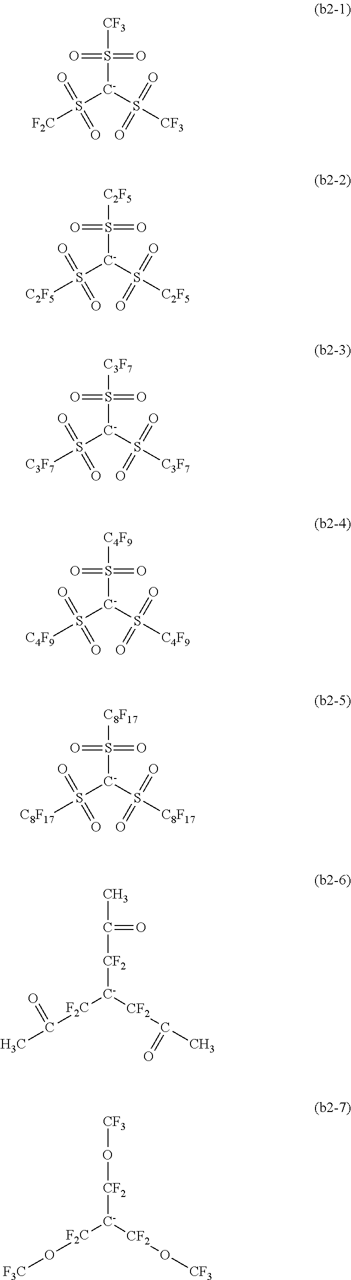

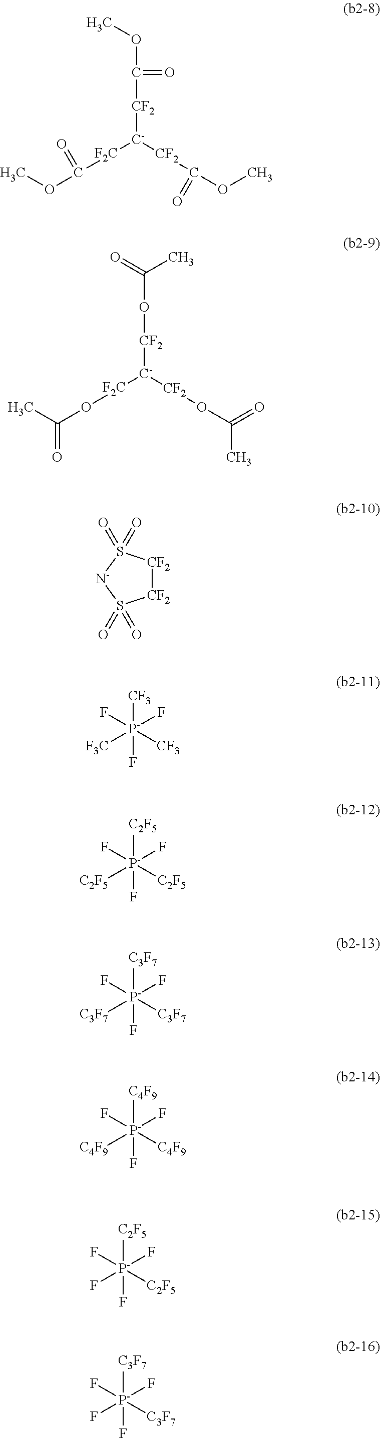

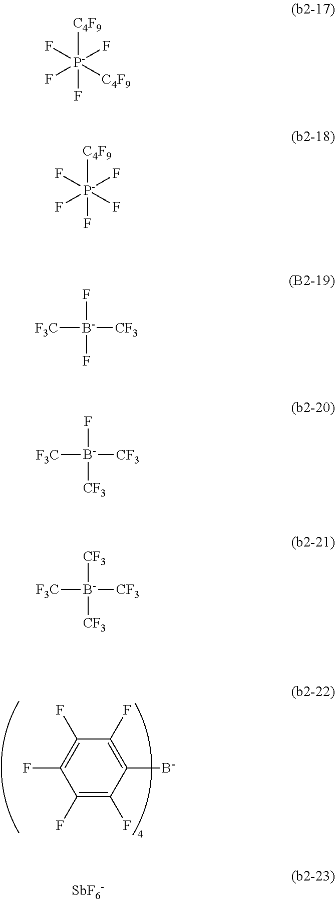

Combinations of the cation structure represented by formula (b1) and the anion structure represented by formula (b2) can be exemplified below:

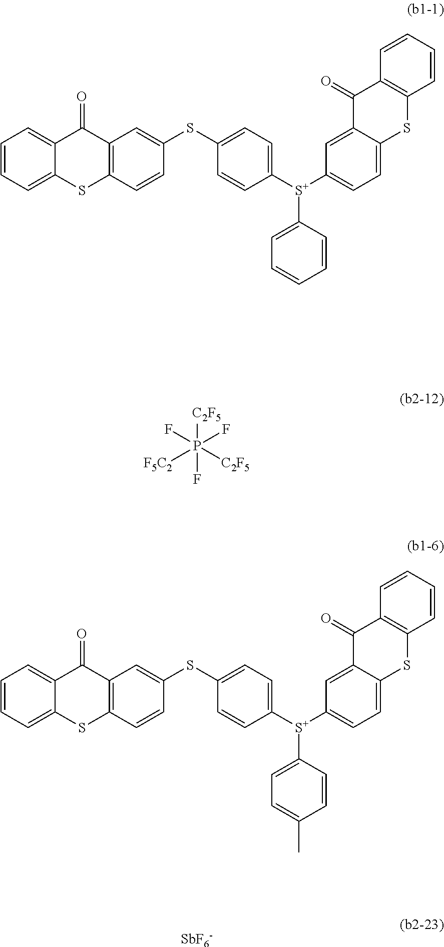

In the case where the photopolymerization initiator (B) is used, the use of the photopolymerization initiator (B) that absorbs 50% or more of the amount of the i-line (light having a wavelength of 365 nm) absorbed by the negative photosensitive resin composition can provide high photosensitivity. That is, high hydrophilicity can be provided at lower exposure intensity.

A single type of the photopolymerization initiator (B) may be used. Alternatively, two or more types of the photopolymerization initiator (B) may be used in combination. The negative photosensitive resin composition preferably has a photopolymerization initiator (B) content of 0.01% or more by mass and 20% or less by mass, more preferably 0.1% or more by mass and 10% or less by mass based on the total solid content of the negative photosensitive resin composition. When the negative photosensitive resin composition has a photopolymerization initiator (B) content within the range described above, a more improved effect of inhibiting the sticking or aggregation of the ink component on the ejection surface is provided.

### Organic Solvent

The organic solvent is not limited to any particular organic solvent. The organic solvent can dissolve components used for the preparation of the negative photosensitive resin composition. Examples of the organic solvent include alkylene glycol monoalkyl ether carboxylates, alkylene glycol monoalkyl ether, alkyl lactates, alkyl alkoxypropionates, cyclic lactones (that can have 4 to 10 carbon atoms), optionally ring-containing monoketone compounds (that can have 4 to 10 carbon atoms), alkylene carbonates, alkyl alkoxyacetates, alkyl pyruvates, benzene ring-containing compounds, and alkyl alcohols (that can have 1 to 12 carbon atoms).

Examples of alkylene glycol monoalkyl ether carboxylates include propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, and ethylene glycol monoethyl ether acetate.

Examples of alkylene glycol monoalkyl ether include propylene glycol monomethyl ether, propylene glycol monoethyl ether, propylene glycol monopropyl ether, propylene glycol monobutyl ether, ethylene glycol monomethyl ether, and ethylene glycol monoethyl ether.

Examples of alkyl lactates include methyl lactate, ethyl lactate, propyl lactate, and butyl lactate.

Examples of alkyl alkoxypropionates include ethyl 3-ethoxypropionate, methyl 3-methoxypropionate, methyl 3-ethoxypropionate, and ethyl 3-methoxypropionate.

Examples of cyclic lactones include β-propiolactone, β-butyrolactone, γ-butyrolactone, α-methyl-γ-butyrolactone, β-methyl-γ-butyrolactone, γ-valerolactone, γ-caprolactone, γ-octanoic lactone, and α-hydroxy-γ-butyrolactone.

Examples of optionally ring-containing monoketone compounds include 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopeantanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, and 3-methylcycloheptanone.

Examples of alkylene carbonates include propylene carbonate, vinylene carbonate, ethylene carbonate, and butylene carbonate.

Examples of alkyl alkoxyacetates include 2-methoxyethyl acetate, 2-ethoxyethyl acetate, 2-(2-ethoxyethoxy)ethyl acetate, 3-methoxy-3-methylbutyl acetate, and 1-methoxy-2-propyl acetate.

Examples of alkyl pyruvates include methyl pyruvate, ethyl pyruvate, and propyl pyruvate.

Examples of benzene ring-containing compounds include benzene, toluene, ethylbenzene, o-xylene, m-xylene, and p-xylene. When the term “xylene” is used, the xylene may be a mixture of, for example, o-xylene, m-xylene, p-xylene, and ethylbenzene.

Examples of alkyl alcohols include methanol, ethanol, 1-propanol, 2-propanol, tert-butyl alcohol, 1-butanol, 2-butanol, isobutyl alcohol, 1-hexanol, 2-hexanol, 3-hexanol, 2-methyl-1-pentanol, 3-methyl-1-pentanol, 4-methyl-1-pentanol, 2-methyl-2-pentanol, cyclopentanol, 1-hexanol, cyclohexanol, 1-heptanol, 2-heptanol, 3-heptanol, and 4-heptanol.

These organic solvents may be used alone or in combination of two or more.

The negative photosensitive resin composition preferably has an organic solvent content of 5% or more by mass, more preferably 10% or more by mass. The organic solvent content is preferably 99.5% or less by mass, more preferably 99.0% or less by mass. That is, the organic solvent content is preferably 5% or more by mass and 99.5% or less by mass, more preferably 10% or more by mass and 99.0% or less by mass. When the organic solvent content is 5% or more by mass and 99.5% or less by mass, the coating film having a good coated surface state is easily provided at the time of the application of the negative photosensitive resin composition on the cover layer.

### Other Additives

The negative photosensitive resin composition can contain, for example, additives described below in addition to the polymer (A), the photopolymerization initiator (B), and the organic solvent. That is, examples of the additives that can be used include, but are not particularly limited to, surfactants, sensitizers, light absorbers, polymerization promoters, flame retardants, flame retardant aids, adhesion modifiers, and storage stabilizers, depending on the application. Known additives can be appropriately selected and used as those additives.

### Method for Producing Liquid Ejection Head

A method for producing a liquid ejection head according to an embodiment of the present disclosure includes a step (c) of applying a negative photosensitive resin composition to form a coating film, a step (d) of subjecting the coating film to exposure, and after the step of subjecting the coating film to exposure, a step of performing heating at 120° C. or higher.

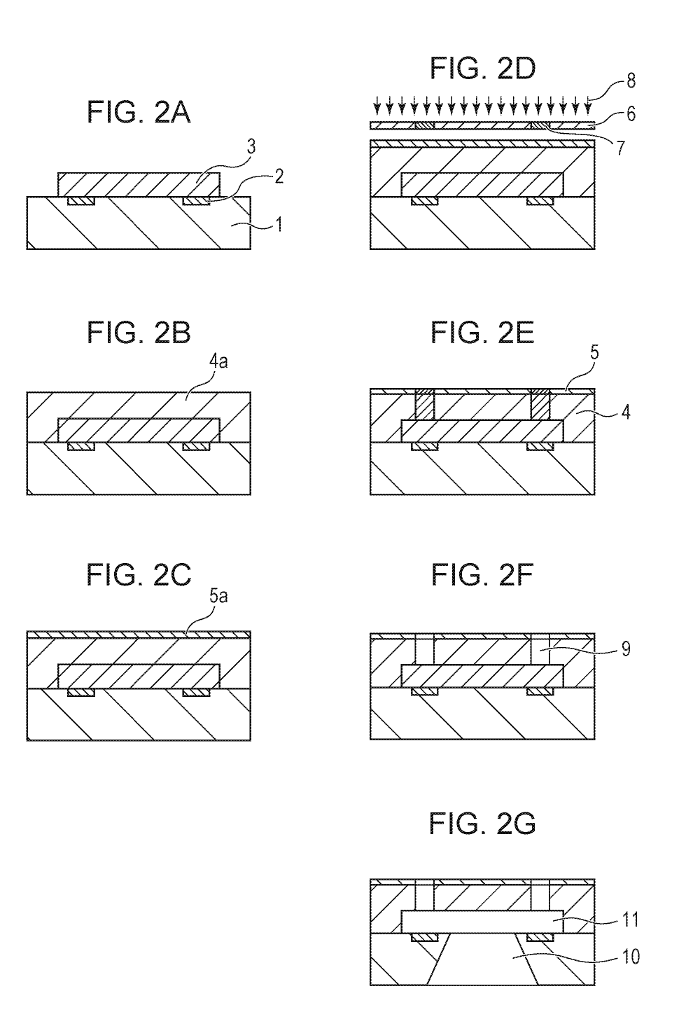

The steps in the method for producing a liquid ejection head according to an embodiment of the present disclosure will be described below with reference to FIGS. 2A to 2G. FIGS. 2A to 2G are cross-sectional views taken along line II-II of FIG. 1 which illustrates the liquid ejection head, the views illustrating the steps.

### Step (a)

As illustrated in FIG. 2A, a pattern-forming member 3 to form a channel is formed on the substrate 1 on which the energy-generating elements 2 are arranged. As the substrate 1, for example, a silicon substrate composed of single-crystal silicon can be used.

The pattern-forming member 3 can be formed by, for example, forming a positive photosensitive resin layer containing a positive photosensitive resin on the substrate 1 and patterning the positive photosensitive resin layer. The positive photosensitive resin layer is not particularly limited, and a layer having resistance to the formation and the patterning of the cover layer 4a can be used. For example, when the cover layer 4a is formed by application, the resin needs to have resistance to a solvent contained in an application solution in such a manner that a pattern did not collapse. As the positive photosensitive resin, a positive resist composed of a photodegradable polymer can be used. Specific examples thereof include poly(methyl isopropenyl ketone), poly(methyl methacrylate), and polymethylglutarimide. The positive photosensitive resin can be exposed at the time of the exposure of the cover layer 4a to cause pattern defects and thus can be a material having low absorbance at an exposure wavelength used for the cover layer 4a. An example of the positive photosensitive resin is poly(methyl isopropenyl ketone). These positive photosensitive resins may be used alone or in combination of two or more.

The positive photosensitive resin layer can be formed by, for example, appropriately dissolving the positive photosensitive resin in a solvent, performing the application of the resulting solution by spin coating, and performing baking to evaporate the solvent. The thickness of the positive photosensitive resin layer corresponds to the height of the channel, is appropriately determined by the design of the liquid ejection head, and can be, but is not particularly limited to, for example, 5 to 30 μm. The positive photosensitive resin layer can be patterned by, for example, a method described below. The positive photosensitive resin layer is exposed to active energy radiation to which the positive photosensitive resin is sensitive, through, if necessary, a mask to perform pattern exposure. Then development is performed with, for example, a solvent capable of dissolving the exposed portion of the positive photosensitive resin, thereby forming the pattern-forming member 3.

### Step (b)

As illustrated in FIG. 2B, the cover layer 4a to be formed into the member 4 is formed on the pattern-forming member 3 and the substrate 1. The cover layer 4a can contain a cationically polymerizable resin and a photopolymerization initiator. Examples of the cationically polymerizable resin include cationically polymerizable resins containing an epoxy group, a vinyl ether group, or an oxetanyl group. However, a cationically polymerizable resin containing an epoxy group can be used from the viewpoint of achieving high mechanical strength and high adhesion to an underlying layer. Examples of the cationically polymerizable resin containing an epoxy group include epoxy resins such as bisphenol A-type epoxy resins and novolac-type epoxy resins. Examples of a commercially available cationically polymerizable resin containing an epoxy group include SU-8 (trade name, available from Nippon Kayaku Co., Ltd.) and EHPE 3150 (trade name, available from Daicel Corporation). These may be used alone or in combination of two or more. The cationically polymerizable resin containing an epoxy group preferably has an epoxy equivalent of 2,000 or less, more preferably 1,000 or less. At at an epoxy equivalent of 2,000 or less, the crosslink density is not decreased during a curing reaction, thus enabling inhibition of a decrease in the glass transition temperature and the adhesion of a cured product. The lower limit of the epoxy equivalent can be, but is not particularly limited to, for example, 50 or more. The epoxy equivalent is a value measured according to JIS K 7236. A high flowability of the coating film 5a described below can decrease the resolution; thus, the cationically polymerizable resin can be solid at 35° C. or lower.

As the photopolymerization initiator, for example, an ionic onium salt such as a sulfonium salt or an iodonium salt can be used. However, an onium salt containing an anion of P(CF₃)₃F₃, which is a fluorine-substituted phosphorous compound, SbF₆, which is an antimony compound, or B(C₆F₅)₄, which is a fluorine-substituted boron compound, can be used in view of the degree of cationic polymerization activity. Examples of a commercially available photopolymerization initiator include Adeka Optomer SP-172 (trade name, available from Adeka Corporation) and CPI-410S (trade name, available from San-Apro Ltd).

The cover layer 4a can be formed by, for example, applying a solution in which materials for the cover layer 4a have been appropriately dissolved in a solvent to the pattern-forming member 3 and the substrate 1 by a spin coating method. When the solvent is used, a solvent that does not easily dissolve the pattern-forming member 3 can be selected and used. The thickness of the cover layer 4a can be, but is not particularly limited to, for example, 0.5 to 100 μm on the pattern-forming member 3.

### Step (c)

As illustrated in FIG. 2C, the coating film 5a to be formed into the hydrophilic layer 5 is formed on the uncured cover layer 4a. The coating film 5a can be formed by the application of a solution containing the negative photosensitive resin composition that contains the polymer (A). The epoxy group-containing cationically polymerizable resin and the photopolymerization initiator can be diffused into the coating film 5a during the application of the solution, which is not a problem. In the case where the photopolymerization initiator is diffused into the coating film 5a, the following advantages can be provided: for example, an acid originating from the photopolymerization initiator promotes the epoxy polymerization reaction in the coating film 5a to improve the adhesion of the hydrophilic layer 5; and the acid promotes the deprotection reaction of the acrylic ester in the coating film 5a, so that a large number of carboxy groups are formed to improve the hydrophilicity.

Examples of a method for applying the solution containing the negative photosensitive resin composition include a spin coating method and a slit coating method. The coating film 5a can have a thickness in such a manner that the hydrophilic layer 5 has a thickness of 50 to 20,000 nm. The coating film 5a may be formed on the whole or part of the surface of the cover layer 4a. For example, when the coating film 5a is partially formed, the coating film 5a can be formed around the ejection orifices 9.

Although the exemplary method described above is a method for forming the coating film 5a on the cover layer 4a by a spin coating method or a slit coating method, the formation of the hydrophilic layer 5 is not limited to the method. For example, a film corresponding to the coating film 5a may be formed by applying a negative photosensitive resin component according to an embodiment of the present disclosure to a base film, drying the resulting wet coating to form a dry film, and laminating the dry film on the cover layer 4a.

### Step (d)

As illustrated in FIG. 2D, the cover layer 4a and the coating film 5a are subjected to pattern exposure. For example, curing regions of the cover layer 4a and the coating film 5a are irradiated with light 8 through a mask 6 having light-shielding portions 7. As the light 8, for example, ultraviolet radiation can be used. The ultraviolet radiation is not particularly limited as long as it has a wavelength to which the photopolymerization initiator is sensitive. For example, the i-line, KrF light, which has a single wavelength, or broadband wavelength light can be used. An example of an i-line light source is an FPA-3030i5+(trade name, available from CANON KABUSHIKI KAISHA). An example of a KrF light source is an FPA-6300ES6a (trade name, available from CANON KABUSHIKI KAISHA). An example of a broadband wavelength light source is a CE-9000 (trade name, available from Ushio Electric Inc).

### Step (e)

As illustrated in FIG. 2E, the cover layer 4a and the coating film 5a are heated to cure the exposed portions. Thereby, the hydrophilic layer 5 composed of the cured product of the negative photosensitive resin composition is formed on the ejection surface. The heat treatment promotes a reaction in the exposed portions to improve resistance to the subsequent development step (f). In this step, ether linkages are formed between the cover layer 4a and the coating film 5a by the polymerization reaction of the epoxy groups. Thus, in particular, when the cover layer 4a and the coating film 5a are cured in one operation, strong bonding is formed between the cover layer 4a and the coating film 5a, providing the hydrophilic layer 5 having high adhesion. The heating temperature and the heating time may be appropriately selected, depending on the materials of the cover layer 4a and the coating film 5a. For example, heating can be performed at 50° C. to 220° C. for 1 minute to 2 hours.

In this step, when heating is performed at 120° C. or higher, this step includes a step of performing heating at 120° C. or higher.

### Step (f)

As illustrated in FIG. 2F, unexposed portions of the cover layer 4a and the coating film 5a are removed to form the ejection orifices 9. The unexposed portions of the cover layer 4a and the coating film 5a can be removed by development with a developing solution. The developing solution is not particularly limited as long as it can develop the unexposed portion of the cover layer 4a and the coating film 5a. For example, a mixture of methyl isobutyl ketone (MIBK) and xylene can be used. After the development treatment, rinse treatment can be performed with, for example, isopropanol. After the formation of the ejection orifices 9, heat treatment may be performed. The heat treatment can provide the stable cured member 4 and the stable cured hydrophilic layer 5. The boundary between the member 4 and the hydrophilic layer 5 need not be clear. The hydrophilic layer 5 only needs to be arranged on the member 4. The heating temperature and the heating time may be appropriately selected, depending on the materials of the cover layer 4a and the coating film 5a. For example, heating can be performed at 120° C. to 220° C. for 1 minute to 2 hours.

In this step, when heating is performed at 120° C. or higher, this step includes a step of performing heating at 120° C. or higher.

### Step (g)

As illustrated in FIG. 2G, the supply port 10 is formed in the substrate 1. The pattern-forming member 3 is removed to form liquid channel 11 communicating with the ejection orifices 9 and the supply port 10. When the substrate 1 is a silicon substrate, the supply port 10 can be formed by silicon processing technology such as anisotropic etching with an alkaline solution. The pattern-forming member 3 can be removed by, for example, immersing the substrate 1 in a solvent capable of dissolving the pattern-forming member 3. If necessary, the pattern-forming member 3 may be exposed to active energy radiation that can decompose the pattern-forming member 3 to increase the solubility of the pattern-forming member 3. After removal of the pattern-forming member 3, the resulting structure can be heated in order to stabilize the structure. The heating temperature and the heating time may be appropriately selected, depending on the material of the structure. For example, heating can be performed at 120° C. to 220° C. for 1 minute to 24 hours. For example, heating at 200° C. for 1 hour sufficiently promotes a chemical reaction such as a polymerization reaction in the member 4 and the hydrophilic layer 5 to provide the more stable structure.

In this step, when heating is performed at 120° C. or higher, this step includes a step of performing heating at 120° C. or higher.

### Step of Performing Heating at 120° C. or Higher

The step of performing heating at 120° C. or higher may be performed anytime as long as it is performed after the step (d) of performing exposure. Specifically, at least any of the steps (e), (f), and (g), which are steps performed after the step (d), may include a step of performing heating at 120° C. or higher. By the step of performing heating at 120° C. or higher, the deprotection reaction of the ester in the polymer (A) contained in the negative photosensitive resin composition proceeds to form carboxy groups. In the step of performing heating at 120° C. or higher, the heating temperature can be 120° C. or higher and 240° C. or lower in view of the heat resistance of organic compounds. The heating time can be, for example, 1 minute to 50 hours.

When the polymer (A) contains (a3), the deprotection reaction of the ester in the (a3) can occur in the step (f) or (g) performed after the step (e). That is, heating can be performed at lower than 120° C. in the step (e), and heating can be performed at 120° C. or higher in the step (f) or (g). This inhibits the consumption of the carboxy groups formed by the deprotection reaction of the ester in (a3) by reaction with the epoxide in (a1) during the heating in the step (e). As a result, many carboxy groups can be formed on the ejection surface of the liquid ejection head in the subsequent step (f) or (g), thus further inhibiting the formation of sticking matter on the ejection surface. In this case, the heating temperature in the step (e) is preferably 80° C. or higher and lower than 120° C., particularly preferably 80° C. or higher and 100° C. or lower.

Electrical bonding to drive the energy-generating elements 2 is performed. For example, a liquid supply member to supply a liquid is connected, thus providing the liquid ejection head including the ejection surface having the cured product of the negative photosensitive resin composition.

### Printer and Printing Method

The liquid ejection head according to an embodiment of the present disclosure can be used for a printer. The liquid ejection head according to an embodiment of the present disclosure can be used in a printing method with the printer. Specifically, the printing method is a method in which a pigment ink containing a pigment is ejected from the printer to provide the pigment ink to a printing medium. Examples of the pigment ink include a pigment ink (resin dispersion-type pigment ink) in which fine pigment particles are coated with a resin, the outermost surfaces of the resin-containing fine pigment particles being electrically charged, the charges of the resin providing dispersion stability; a pigment ink (self-dispersible pigment ink) in which the outermost surfaces of the fine pigment particles themselves are electrically charged to provide dispersion stability. The liquid ejection head according to an embodiment of the present disclosure can be used for both of the resin dispersion-type pigment ink and the self-dispersible pigment ink, and can be particularly used in the printing method with the resin dispersion-type pigment ink.

### EXAMPLES

While a method for producing a liquid ejection head according to an embodiment of the present disclosure will be described below by examples, the present disclosure is not limited to these examples.

### Example 1

As illustrated in FIG. 2A, the pattern-forming member 3 was formed on the substrate 1 on which the energy-generating elements 2 are arranged. Specifically, poly(methyl isopropenyl ketone) was dissolved in cyclohexane, and the resulting solution was applied to the substrate 1 by a spin coating method. Baking was then performed at 120° C. for 300 seconds to evaporate the solvent, thereby forming a positive photosensitive resin layer having a thickness of 15 μm. The positive photosensitive resin layer was subjected to pattern exposure by irradiation with broadband wavelength light using a CE-9000 (trade name, available from Ushio Electric Inc.) through a mask. The exposed portion of the positive photosensitive resin layer was developed with propylene glycol monomethyl ether acetate to form the pattern-forming member 3.

As illustrated in FIG. 2B, the cover layer 4a was formed on the pattern-forming member 3 and the substrate 1. Specifically, a negative photosensitive resin composition prepared by dissolving EHPE 3150 (trade name, available from Daicel Corporation) and Adeka Optomer SP-172 (trade name, available from Adeka Corporation) in xylene was applied to the pattern-forming member 3 and the substrate 1 by a spin coating method. Baking was then performed at 90° C. for 300 seconds to evaporate the solvent, thereby forming a negative photosensitive resin layer having a thickness of 5 μm on the pattern-forming member 3 and 20 μm on a portion of the substrate 1 where the pattern-forming member 3 was absent.

As illustrated in FIG. 2C, the coating film 5a composed of a negative photosensitive resin composition containing a polymer (A) was formed on the uncured cover layer 4a. Specifically, the negative photosensitive resin composition containing the polymer (A), a photopolymerization initiator (B), and an organic solvent listed in Table 1 was applied to the cover layer 4a by a slit coating method. Baking was then performed at 70° C. for 180 seconds to evaporate the solvent, thereby forming the coating film 5a having a thickness of 1 μm.

As illustrated in FIG. 2D, the cover layer 4a and the coating film 5a were subjected to pattern exposure by irradiation with the i-line using an FPA-3030i5+ (trade name, available from CANON KABUSHIKI KAISHA) through a mask. The light source and the exposure intensity as listed in Table 1 were used.

As illustrated in FIG. 2E, baking was performed at 95° C. for 240 seconds to heat the cover layer 4a and the coating film 5a, thereby curing exposed portions.

As illustrated in FIG. 2F, development was performed with a mixture of xylene and methyl isobutyl ketone to remove unexposed portions of the cover layer 4a and the coating film 5a, thereby forming the ejection orifices 9.

As illustrated in FIG. 2G, the supply port 10 and the liquid channel 11 were formed. Specifically, anisotropic etching was performed with an alkaline solution at 80° C. for 16 hours to form the supply port 10. After photoirradiation was performed with a CE-9000 (trade name, available from Ushio Electric Inc.), the pattern-forming member 3 was removed by immersing the substrate 1 in propylene glycol monomethyl ether acetate, thereby forming the liquid channel 11. After the pattern-forming member 3 was removed, heating was performed at 200° C. for 1 hour. Thereby, a liquid ejection head according to Example 1 was produced.

### Examples 2 to 10 and Comparative Examples 1 to 4

Liquid ejection heads were produced as in Example 1, except that compositions of the negative photosensitive resin composition contained in the coating film 5a, exposure conditions in the step (d), and the heating temperature were changed as listed in Table 1. In each of the boxes of the section “heating temperature” in the table, the highest heating temperature in the heating step and the step including the heating temperature are described. In Example 6, an FPA-6300ES6a (trade name, available from CANON KABUSHIKI KAISHA) was used as a KrF light source. The term “absorption rate of (B) for i-line” in Example 6 refers to “absorption rate of (B) for KrF light”.

### Evaluation

The resulting liquid ejection heads were evaluated as described below. Table 1 lists the results.

### Study on Development of Hydrophilic Group

The dynamic receding contact angle θr of pure water was used as an index of the formation of hydrophilic groups such as carboxy groups and hydroxy groups on the ejection surface. The dynamic receding contact angle θr was measured with a micro-contact angle meter (trade name: DropMeasure, available from Microjet).

In this evaluation, the case of a low dynamic receding contact angle θr of 30° or less was defined as having “high hydrophilicity” or being “highly hydrophilic”. In the case of a dynamic receding contact angle θr of 30° or less, the ejection surface was determined to be in a state where the hydrophilic groups were sufficiently formed on the ejection surface to develop the hydrophilicity. The lower measurement limit in the method for measuring a contact angle was 15°. A contact angle of less than 15° cannot be quantified. Thus, in Table 1, when the contact angle was less than the lower measurement limit, the angle was expressed as “<15°”.

### Study on Maintenance of Hydrophilicity

The ejection surface of each of the liquid ejection head was immersed in a pigment-containing ink. The ejection surface continued to be immersed under accelerated conditions (at a heating temperature of 60° C. for 7 days). Then the ejection surface was sufficiently rinsed, and the dynamic receding contact angle θr was measured again. When a low dynamic receding contact angle θr of 30° or less was obtained, the hydrophilicity was determined to be maintained. As the pigment-containing ink, a resin dispersion-type pigment ink was used in Examples 1 to 9 and Comparative examples 1 to 3, and a self-dispersible pigment ink was used in Example 10 and Comparative example 4.

### Study on Sticking Matter

Peripheries of the ejection orifices of each of the ejection surfaces, where sticking matter was liable to be formed, were observed with a metallurgical microscope (trade name: ECLIPSE L200, available from Nikon Corporation) at a magnification of an eyepiece of ×10 and a magnification of an objective lens of ×100. Ten ejection orifices were observed for each liquid ejection head to determine whether the sticking matter was formed or not.

### Evaluation of Printing

Solid printing was performed with each of the liquid ejection heads of Examples 1 to 10 and Comparative examples 1 to 4 in one pass on the entire surface of printing paper HR-101s (trade name, inkjet printing paper, available from CANON KABUSHIKI KAISHA) at a distance between the paper and the head of 1.9 mm. The printed paper was visually observed. When a white streak was observed, the liquid ejection head was determined to be NG. When no white streak was observed, the liquid ejection head was determined to be OK.

TABLE 1

| | | | Example 1 | Example 2 | Example 3 | Example 4 | Example 5 | Example 6 | Example 7 |
|---|---|---|---|---|---|---|---|---|---|
| Negative | Polymer (A) | Type | (A-1) | (A-2) | (A-2) | (A-3) | (A-4) | (A-4) | (A-5) |
| photosensitive resin | | Amount added | 100 | 100 | 100 | 100 | 100 | 100 | 100 |
| composition | | (% by mass) | | | | | | | |
| | Photopolymerization | Type | (B-2) | (B-2) | (B-2) | (B-2) | (B-2) | (B-2) | (B-1) |
| | initiator (B) | Amount added | 10 | 8 | 8 | 5 | 5 | 5 | 5 |
| | | (% by mass) | | | | | | | |
| | | Absorption rate of | 91 | 90 | 90 | 85 | 89 | 89 | 92 |
| | | (B) for i-line | | | | | | | |
| | Organic solvent | Type | C-1/C-3 | C-1/C-3 | C-1/C-3 | C-2/C-3 | C-2/C-3 | C-2/C-3 | C-1/C-2 |
| | | Amount added | 200/1200 | 300/1100 | 300/1100 | 400/1000 | 500/900 | 500/900 | 1000/400 |
| | | (% by mass) | | | | | | | |
| | Others | Crosslinker | | | | | | | |
| | | Light absorber | | | | | | | |
| | | Amount added | | | | | | | |
| | | (% by mass) | | | | | | | |
| Process | Exposure condition | Light source/ | i-line/ | i-line/ | i-line/ | i-line/ | i-line/ | KrF/1000 | i-line/ |
| | | exposure intensity | 1500 | 5000 | 5000 | 1000 | 4000 | | 1500 |
| | | (J/m²) | | | | | | | |
| | Heating temperature | Temperature/step | 200° C./ | 140° C./ | 125° C./ | 200° C./ | 200° C./ | 200° C./ | 120° C./ |
| | | | (g) | (f) | (e) | (g) | (g) | (g) | (f) |

| Evaluation | Ink | Resin dispersion type/ | Resin dispersion type | | | | | | |
|---|---|---|---|---|---|---|---|---|---|
| | | self-dispersing type | | | | | | | |
| | Evaluation | Development of hydrophilic group (θr) | <15° | <15° | <15° | 17° | <15° | <15° | 18° |
| | result | Maintenance of hydrophilicity (θr) | <15° | <15° | <15° | 19° | <15° | <15° | 20° |
| | | Sticking matter | no | no | no | no | no | no | no |
| | | Evaluation of printing | OK | OK | OK | OK | OK | OK | OK |

| | | | | | | Com- | Com- | Com- | |
|---|---|---|---|---|---|---|---|---|---|
| | | | | | Example | parative | parative | parative | Comparative |
| | | | Example 8 | Example 9 | 10 | example 1 | example 2 | example 3 | example 4 |
| Negative | Polymer (A) | Type | (A-6) | (A-7) | (A-1) | (A′-1) | (A′-2) | (A′-3) | (A′-2) |
| photosensitive resin | | Amount added | 100 | 100 | 100 | 100 | 100 | 100 | 100 |
| composition | | (% by mass) | | | | | | | |
| | Photopolymerization | Type | (B-1) | (B-2) | (B-2) | (B-2) | (B-2) | (B-2) | (B-2) |
| | initiator (B) | Amount added | 1 | 5 | 10 | 5 | 5 | 5 | 5 |
| | | (% by mass) | | | | | | | |
| | | Absorption rate of | 60 | 55 | 91 | 85 | 86 | 95 | 86 |
| | | (B) for i-line | | | | | | | |
| | Organic solvent | Type | C-1/C-2 | C-1/C-2 | C-1/C-3 | C-3 | C-2/C-3 | C-1/C-2 | C-2/C-3 |
| | | Amount added | 1000/400 | 1000/400 | 200/1200 | 1600 | 400/1000 | 1000/400 | 400/1000 |
| | | (% by mass) | | | | | | | |
| | Others | Crosslinker | | | | (D-1) | | | |
| | | Light absorber | | (D-2) | | | | | |
| | | Amount added | | 0.5 | | 20 | | | |
| | | (% by mass) | | | | | | | |
| Process | Exposure condition | Light source/ | i-line/ | i-line/ | i-line/ | i-line/1500 | i-line/1500 | i-line/1500 | i-line/1500 |
| | | exposure intensity | 1500 | 1500 | 1500 | | | | |
| | | (J/m²) | | | | | | | |
| | Heating temperature | Temperature/step | 200° C./ | 200° C./ | 200° C./ | 200° C./ | 115° C./ | 200° C./ | 115° C./(f) |
| | | | (g) | (g) | (g) | (g) | (f) | (g) | |

| Evaluation | Ink | Resin dispersion type/ | Resin dispersion type | | Self- | Resin dispersion type | | | Self- |
|---|---|---|---|---|---|---|---|---|---|
| | | self-dispersing type | | | dispersing | | | | dispersing |
| | | | | | type | | | | type |
| | Evaluation | Development of hydrophilic group (θr) | 19° | 25° | <15° | 58° | 36° | 62° | 36° |
| | result | Maintenance of hydrophilicity (θr) | 21° | 28° | <15° | 63° | 43° | 65° | 39° |
| | | Sticking matter | no | no | no | large | small | large | small |
| | | | | | | amount | amount | amount | amount |
| | | Evaluation of printing | OK | OK | OK | NG | NG | NG | NG |

In Table 1, the polymer (A), the photopolymerization initiator (B), the organic solvent, the crosslinker, and the light absorber used in the examples and the comparative examples are described below.

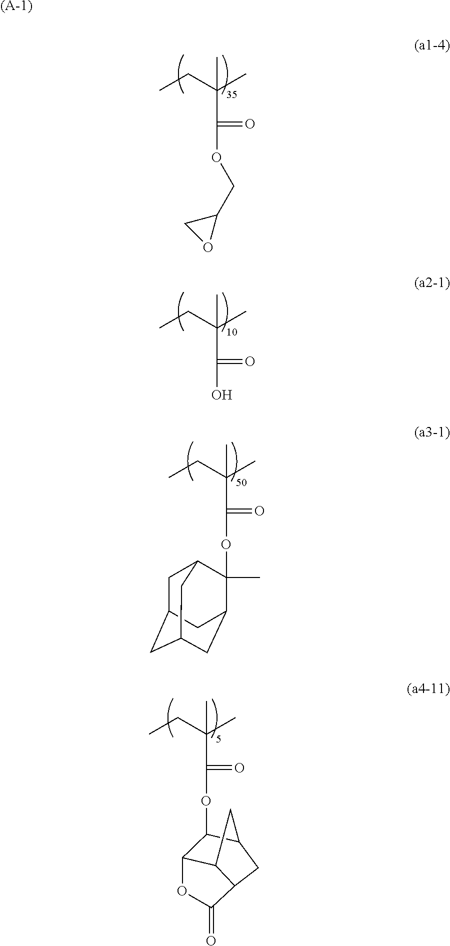

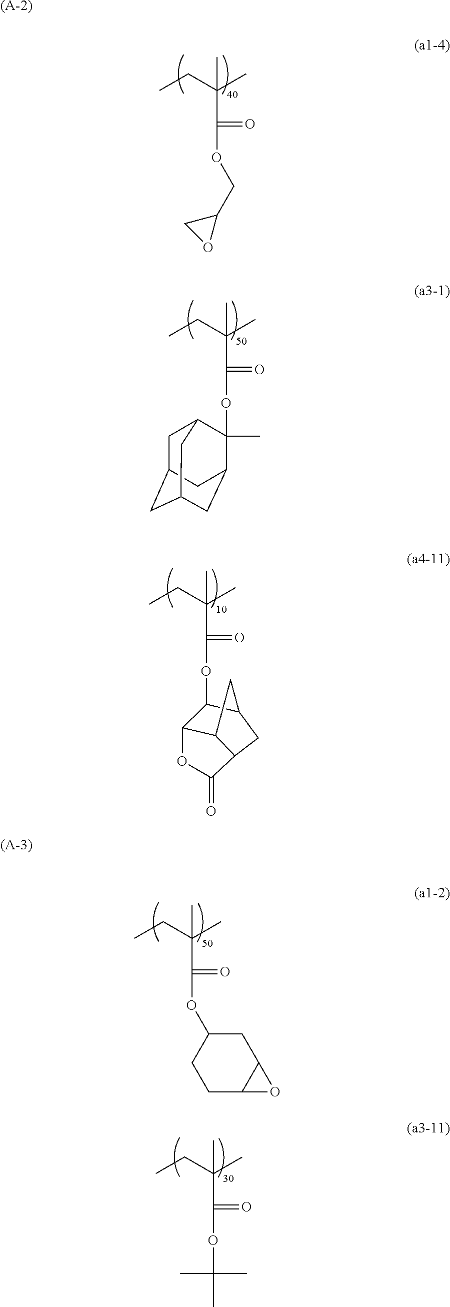

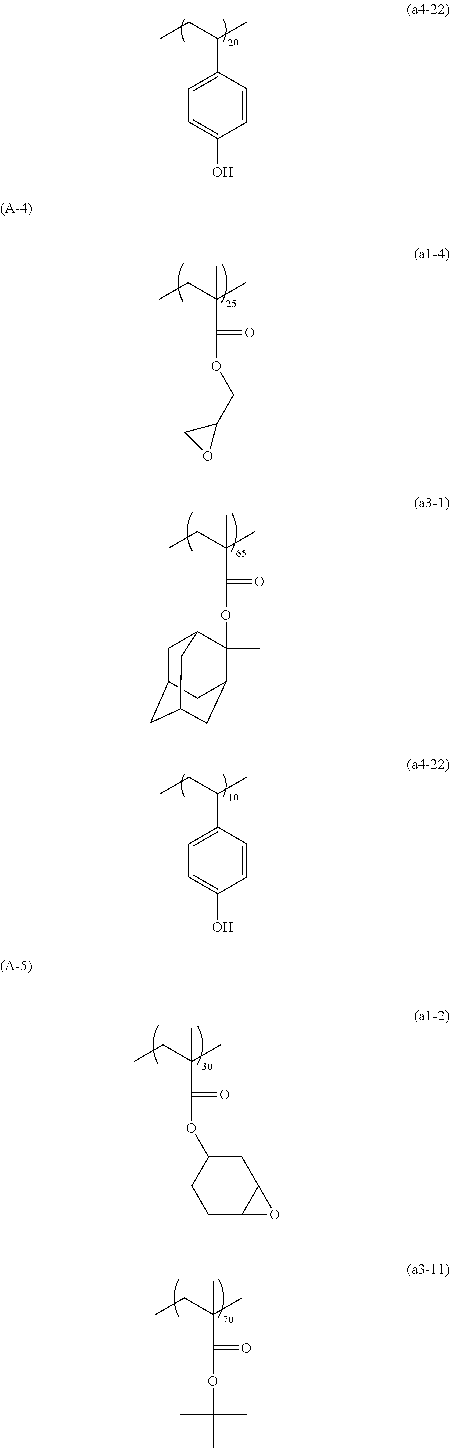

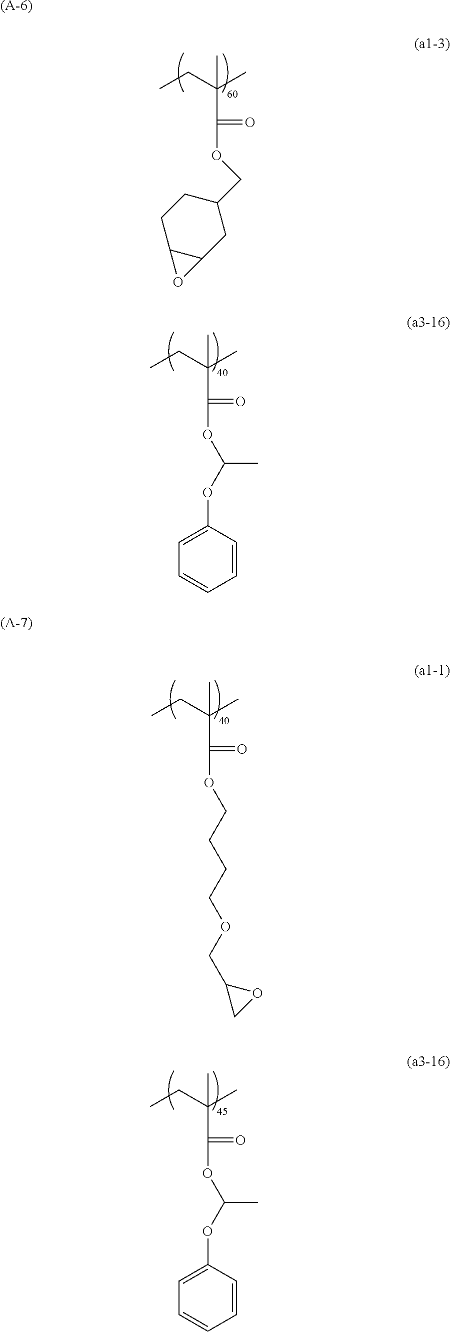

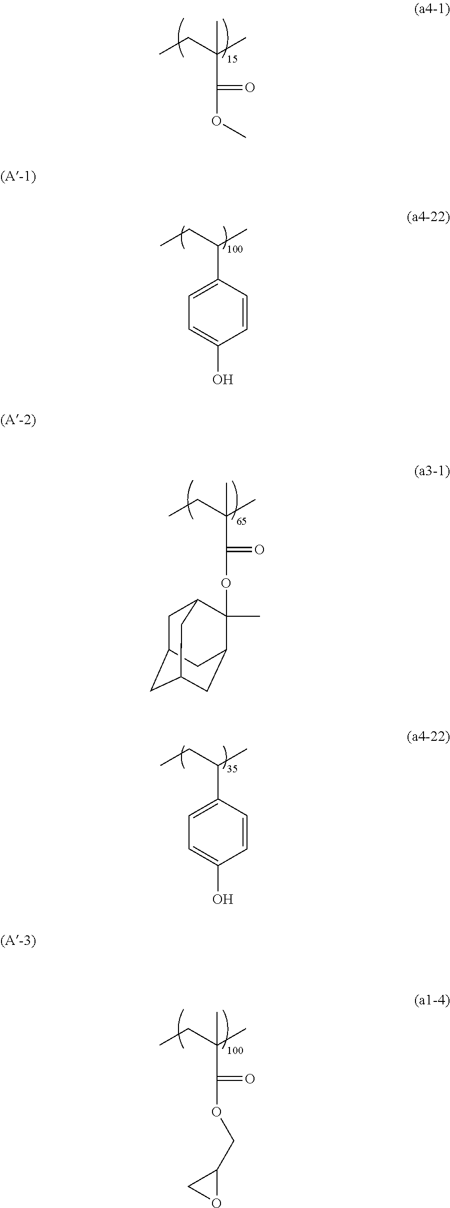

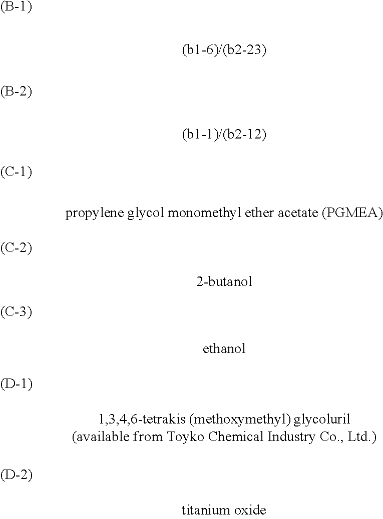

The results listed in Table 1 indicated that the liquid ejection heads produced by the method according to an embodiment of the present disclosure had high hydrophilicity, good development of the hydrophilic groups was provided, and the hydrophilicity was maintained even if the liquid ejection heads were exposed to the pigment-containing ink. No sticking matter was observed on each of the ejection surfaces.

In the liquid ejection head according to Comparative example 1, the development of the hydrophilic groups was poor, and a large amount of sticking matter was observed on the ejection surface. This is presumably because the phenolic hydroxy group, which is a hydrophilic group, in the polymer (A′-1) was crosslinked to the crosslinker (D-1) to cause the hydrophilic groups to disappear, thus failing to provide the advantages of the present disclosure. In the liquid ejection head according to Comparative example 2, the development of the hydrophilic groups was poor, and a small amount of sticking matter was observed on the ejection surface. This is presumably because the heating temperature was lower than 120° C., and thus the deprotection reaction of the ester proceeded insufficiently. In the liquid ejection head according to Comparative example 3, the development of the hydrophilic groups was poor, and a large amount of sticking matter was observed on the ejection surface. This is presumably because the polymer (A′-3) used as a negative photosensitive resin composition contained in the coating film 5a did not have a group that induces hydrophilicity, such as a carboxy group, and thus the advantages of the present disclosure were not provided.

The results of the evaluation of printing indicated that no white streak was observed in Examples 1 to 10 and a white streak was observed in each of Comparative examples 1 to 4. The results demonstrated that the presence or absence of the sticking matter corresponds to the presence or absence of the white streak. When the sticking matter was present on the ejection surface, deflection occurred in which the ejected ink landed at a point deviating from a predetermined landing point on the paper by the influence of the sticking matter, possibly causing the white streak. In each of the liquid ejection heads produced by the method according to an embodiment of the present disclosure, no streak occurred, and good evaluation results of printing were obtained.

As described above, the results indicated that in each of the liquid ejection heads produced by the method according to an embodiment of the present disclosure, the sticking of the ink component on the ejection surface is inhibited even if the pigment-containing ink is used and that the high hydrophilicity of the ejection surface is maintained even if the ejection surface is exposed to the pigment-containing ink. The results also indicated that each of the liquid ejection heads according to an embodiment of the present disclosure is effective for both of the self-dispersible pigment ink and the resin dispersion-type pigment ink and that the high hydrophilicity can be maintained even in a liquid ejection device using the resin dispersion-type pigment ink that more impedes the maintenance of the hydrophilicity.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2016-226551 filed Nov. 22, 2016, which is hereby incorporated by reference herein in its entirety.

What is claimed is:

1. A method for producing a liquid ejection head including an ejection surface having a cured product of a negative photosensitive resin composition, the method comprising the steps of:
applying the negative photosensitive resin composition to form a coating film;
subjecting the coating film to exposure; and
after the step of subjecting the coating film to exposure, performing heating at 120° C. or higher,
wherein the negative photosensitive resin composition contains a polymer (A) containing a unit originating from an epoxy group-containing acrylic ester and at least one selected from a unit originating from acrylic acid and a unit originating from an acrylic ester capable of being deprotected at 120° C. or higher.

2. The method according to claim 1, wherein the polymer (A) contains the unit originating from the epoxy group-containing acrylic ester and the unit originating from the acrylic ester capable of being deprotected at 120° C. or higher.

3. The method according to claim 1, wherein the negative photosensitive resin composition further contains a photopolymerization initiator (B).

4. The method according to claim 1, wherein the negative photosensitive resin composition further contains at least one selected from a unit that originates from an acrylic ester and that is not subjected to deprotection reaction at 120° C. or higher and a unit originating from optionally substituted styrene.

5. The method according to claim 1, wherein the ester in the unit originating from the acrylic ester capable of being deprotected at 120° C. or higher is a tertiary alkyl ester.

6. The method according to claim 1, wherein the proportion of the unit originating from the epoxy group-containing acrylic ester in the polymer (A) is 20% or more and 80% or less in terms of a feeding molar ratio.

7. The method according to claim 1, wherein in the step of subjecting the coating film to exposure, an i-line is used as a light source.

8. The method according to claim 7, wherein the photopolymerization initiator (B) absorbs 50% or more of the amount of the i-line.

9. The method according to claim 1, further comprising the steps of:
after the step of subjecting the coating film to exposure, a step of curing an exposed portion; and
after the step of curing the exposed portion, a step of removing an unexposed portion by development.

10. The method according to claim 9, wherein the step of curing the exposed portion is the step of performing heating at 120° C. or higher.

11. The method according to claim 9, wherein heating is performed at lower than 120° C. in the step of curing the exposed portion, and the step of performing heating at 120° C. or higher is performed after the step of curing the exposed portion.

12. The method according to claim 11, wherein in the step of curing the exposed portion, heating is performed at 80° C. or higher and 100° C. or lower.

13. A liquid ejection head comprising:
an ejection surface having a cured product of a negative photosensitive resin composition,
wherein the negative photosensitive resin composition contains a polymer (A) containing at least one selected from a unit originating from an epoxy group-containing acrylic ester, a unit originating from acrylic acid, and a unit originating from an acrylic ester capable of being deprotected at 120° C. or higher, the cured product containing a carboxy group.

14. A printing method comprising a step of:
ejecting a pigment ink containing a pigment from a liquid ejection head to provide the pigment ink to a printing medium, the pigment comprising a fine pigment particle, the fine pigment particle being coated with a resin, outermost surfaces of the fine pigment particle containing the resin being electrically charged,
wherein the liquid ejection head includes an ejection surface having a cured product of a negative photosensitive resin composition, and
the negative photosensitive resin composition contains a polymer (A) containing a unit originating from an epoxy group-containing acrylic ester and at least one selected from a unit originating from acrylic acid and a unit originating from an acrylic ester capable of being deprotected at 120° C. or higher, the cured product containing a carboxy group.
